(19) United States
(12) Patent Application Publication
(10) Pub. No.: US 2012/0161206 A1
(43) Pub. Date: Jun. 28, 2012

(54) SEMICONDUCTOR MEMORY DEVICE, SEMICONDUCTOR WAFER, AND METHOD FOR MANUFACTURING SEMICONDUCTOR MEMORY DEVICE

(75) Inventor: Hiroshi SHIMODE, Mie-ken (JP)

(73) Assignee: KABUSHIKI KAISHA TOSHIBA, Tokyo (JP)

(21) Appl. No.: 13/236,703

(22) Filed: Sep. 20, 2011

(30) Foreign Application Priority Data
Dec. 24, 2010 (JP) 2010-287480

(51) Int. Cl. H01L 27/08; H01L 21/28

(52) U.S. Cl. 257/202; 438/585; 257/E27.046; 257/E21.158

(57) ABSTRACT

According to one embodiment, a semiconductor memory device includes a memory cell array unit and an alignment mark unit. The cell array unit includes a first memory string, a second memory string and a device isolation insulating layer. The first string is provided on a major surface of a semiconductor layer. The second string is juxtaposed with the first memory string. The device isolation insulating layer partitions the first and second memory strings from each other. The mark unit juxtaposed with the array unit includes a mark unit semiconductor layer and a mark unit insulating layer. The mark unit semiconductor layer is a part of the semiconductor layer. The mark unit insulating layer is juxtaposed with the mark unit semiconductor layer. An upper surface of the mark unit semiconductor layer is included in a plane different from a plane including an upper surface of the mark unit insulating layer.

### CROSS-REFERENCE TO RELATED APPLICATIONS

This application is based upon and claims the benefit of priority from the prior Japanese Patent Application No.2010-287480, filed on Dec. 24, 2010; the entire contents of which are incorporated herein by reference.

### FIELD

Embodiments described herein relate generally to a semiconductor memory device, a semiconductor wafer, and a method for manufacturing the semiconductor memory device.

### BACKGROUND

Memory cells are downscaled as the memory capacity density is increased for types of nonvolatile semiconductor memory devices such as floating-gate types, charge storage layer (MONOS) types, etc. High mask alignment precision is necessary in the manufacturing processes of semiconductor memory devices. Misrecognition of alignment marks occur easily; and productivity decreases.

### BRIEF DESCRIPTION OF THE DRAWINGS

FIG. 1 is a schematic cross-sectional view illustrating the configuration of a part of a semiconductor memory device according to a first embodiment;

FIG. 2 is a schematic plan view illustrating the configuration of the semiconductor memory device according to the first embodiment;

FIG. 3A and FIG. 3B are schematic cross-sectional views illustrating the configuration of a part of the semiconductor memory device according to the first embodiment;

FIG. 4A and FIG. 4B are schematic plan views illustrating the configuration of a part of the semiconductor memory device according to the first embodiment;

FIG. 5 is a flowchart illustrating a method for manufacturing the semiconductor memory device according to the first embodiment;

FIG. 6A to FIG. 6C are schematic cross-sectional views in order of the processes, illustrating the method for manufacturing the semiconductor memory device according to the first embodiment;

FIG. 7A to FIG. 7C are schematic cross-sectional views in order of the processes, illustrating the method for manufacturing the semiconductor memory device according to the first embodiment;

FIG. 8A and FIG. 8B are schematic cross-sectional views in order of the processes, illustrating the method for manufacturing the semiconductor memory device according to the first embodiment;

FIG. 9 is a schematic cross-sectional view illustrating the configuration of a part of a semiconductor memory device of a first reference example;

FIG. 10 is a schematic cross-sectional view illustrating the configuration of a part of a semiconductor memory device according to a second embodiment;

FIG. 11 is a flowchart illustrating the method for manufacturing the semiconductor memory device according to the second embodiment;

FIG. 12A to FIG. 12C are schematic cross-sectional views in order of the processes, illustrating a method for manufacturing the semiconductor memory device according to the second embodiment;

FIG. 13A to FIG. 13B are schematic cross-sectional views in order of the processes, illustrating a method for manufacturing the semiconductor memory device according to the second embodiment;

FIG. 14 is a schematic cross-sectional view illustrating another method for manufacturing the semiconductor memory device according to the embodiment.

FIGS. 15A to 15C are schematic cross-sectional views illustrating the configuration of a part of a semiconductor memory device according to a third embodiment;

FIG. 16 is a schematic plan view illustrating the configuration of the semiconductor memory device according to the third embodiment;

FIG. 17A to FIG. 17C are schematic cross-sectional views in order of the processes, illustrating the method for manufacturing the semiconductor memory device according to the third embodiment;

FIG. 18A to FIG. 18C are schematic cross-sectional views in order of the processes, illustrating the method for manufacturing the semiconductor memory device according to the third embodiment;

FIG. 19A to FIG. 19C are schematic cross-sectional views in order of the processes, illustrating the method for manufacturing the semiconductor memory device according to the third embodiment;

FIG. 20A to FIG. 20C are schematic cross-sectional views in order of the processes, illustrating the method for manufacturing the semiconductor memory device according to the third embodiment;

FIG. 21A to FIG. 21C are schematic cross-sectional views in order of the processes, illustrating the method for manufacturing the semiconductor memory device according to the third embodiment;

FIG. 22A to FIG. 22C are schematic cross-sectional views in order of the processes, illustrating the method for manufacturing the semiconductor memory device according to the third embodiment;

FIG. 23A to FIG. 23C are schematic cross-sectional views in order of the processes, illustrating the method for manufacturing the semiconductor memory device according to the third embodiment;

FIG. 24A to FIG. 24C are schematic cross-sectional views illustrating the configuration of a part of a semiconductor memory device of a second reference example;

FIG. 25A to FIG. 25C are schematic cross-sectional views illustrating the configuration of a part of a semiconductor memory device according to a fourth embodiment;

FIG. 26A to FIG. 26C are schematic cross-sectional views in order of the processes, illustrating the method for manufacturing the semiconductor memory device according to the fourth embodiment;

FIG. 27A to FIG. 27C are schematic cross-sectional views in order of the processes, illustrating the method for manufacturing the semiconductor memory device according to the fourth embodiment;

FIG. 28A to FIG. 28C are schematic cross-sectional views in order of the processes, illustrating the method for manufacturing the semiconductor memory device according to the fourth embodiment;

FIG. 29A to FIG. 29C are schematic cross-sectional views in order of the processes, illustrating the method for manufacturing the semiconductor memory device according to the fourth embodiment; and

FIG. 30A to FIG. 30C are schematic cross-sectional views in order of the processes, illustrating the method for manufacturing the semiconductor memory device according to the fourth embodiment.

### DETAILED DESCRIPTION

In general, according to one embodiment, a semiconductor memory device includes a memory cell array unit and an alignment mark unit. The memory cell array unit includes a first memory string, a second memory string and a device isolation insulating layer. The first memory string is provided on a major surface of a semiconductor layer. The second memory string is juxtaposed with the first memory string on the major surface. The device isolation insulating layer partitions the first memory string and the second memory string from each other. The alignment mark unit is juxtaposed with the memory cell array unit. The alignment mark unit includes a mark unit semiconductor layer and a mark unit insulating layer. The mark unit semiconductor layer is a part of the semiconductor layer. The mark unit insulating layer is juxtaposed with the mark unit semiconductor layer, and includes a material same as a material of the device isolation insulating layer. An upper surface of the mark unit semiconductor layer is included in a plane different from a plane including an upper surface of the mark unit insulating layer when a direction of the major surface side defines the direction of an upper direction.

In general, according to another embodiment, a method is disclosed for manufacturing a semiconductor memory device. The device includes a memory cell array unit and an alignment mark unit juxtaposed with the memory cell array unit. The memory cell array unit includes a first memory string provided on a major surface of a semiconductor layer, a second memory string juxtaposed with the first memory string on the major surface, and a device isolation insulating layer partitioning the first memory string and the second memory string from each other. The alignment mark unit includes a mark unit semiconductor layer and a mark unit insulating layer juxtaposed with the mark unit semiconductor layer. The mark unit semiconductor layer is a part of the semiconductor layer. The mark unit insulating layer includes a material same as a material of the device isolation insulating layer. An upper surface of the mark unit semiconductor layer is included in a plane different from a plane including an upper surface of the mark unit insulating layer when a direction of the major surface side defines the direction of an upper direction. The method can include forming a charge retaining film in a base body upper surface of a base body of a mark unit region. The base body includes the semiconductor layer and the mark unit semiconductor layer. The alignment mark unit is formed in the mark unit region. The charge retaining film is used to form a charge retaining layer included in a memory cell included in the first memory string and a charge retaining layer included in a memory cell included in the second memory string. The method can include making a mark unit trench in the charge retaining film and the base body. The method can include filling an insulating layer into the mark unit trench. In addition, the method can include forming a difference in levels by causing an upper surface of the insulating layer filled into the mark unit trench to be included in a plane different from a plane including the base body upper surface of the base body of the mark unit region by etching at least one selected from the insulating layer filled into the mark unit trench and the base body upper surface of the base body of the mark unit region.

In general, according to another embodiment, a semiconductor wafer includes a memory cell array unit and an alignment mark unit. The memory cell array unit includes a first memory string, a second memory string and a device isolation insulating layer. The first memory string is provided on a major surface of a semiconductor layer. The second memory string is juxtaposed with the first memory string on the major surface. The device isolation insulating layer partitions the first memory string and the second memory string from each other. The alignment mark unit is juxtaposed with the memory cell array unit. The alignment mark unit includes a mark unit semiconductor layer and a mark unit insulating layer. The mark unit semiconductor layer is a part of the semiconductor layer. The mark unit insulating layer is juxtaposed with the mark unit semiconductor layer, and includes a material same as a material of the device isolation insulating layer. An upper surface of the mark unit semiconductor layer is included in a plane different from a plane including an upper surface of the mark unit insulating layer when a direction of the major surface side defines the direction of an upper direction.

Various embodiments will be described hereinafter with reference to the accompanying drawings.

The drawings are schematic or conceptual; and the relationships between the thicknesses and the widths of portions, the proportions of sizes among portions, etc., are not necessarily the same as the actual values thereof. Further, the dimensions and the proportions may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

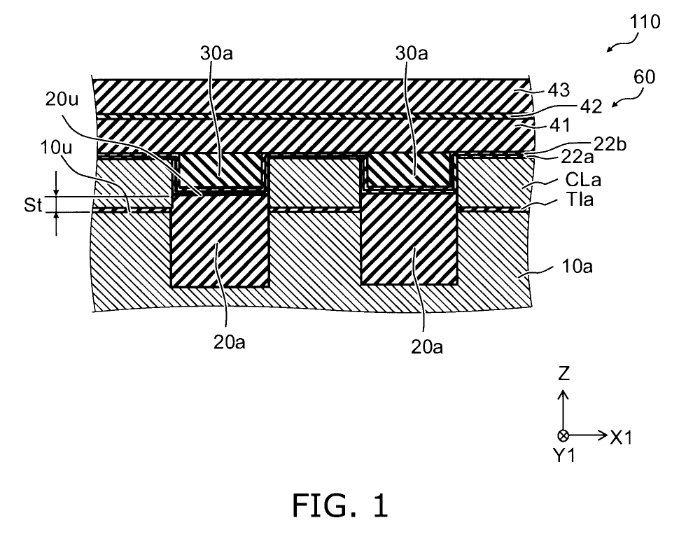

FIG. 1 is a schematic cross-sectional view illustrating the configuration of a part of a semiconductor memory device according to a first embodiment.

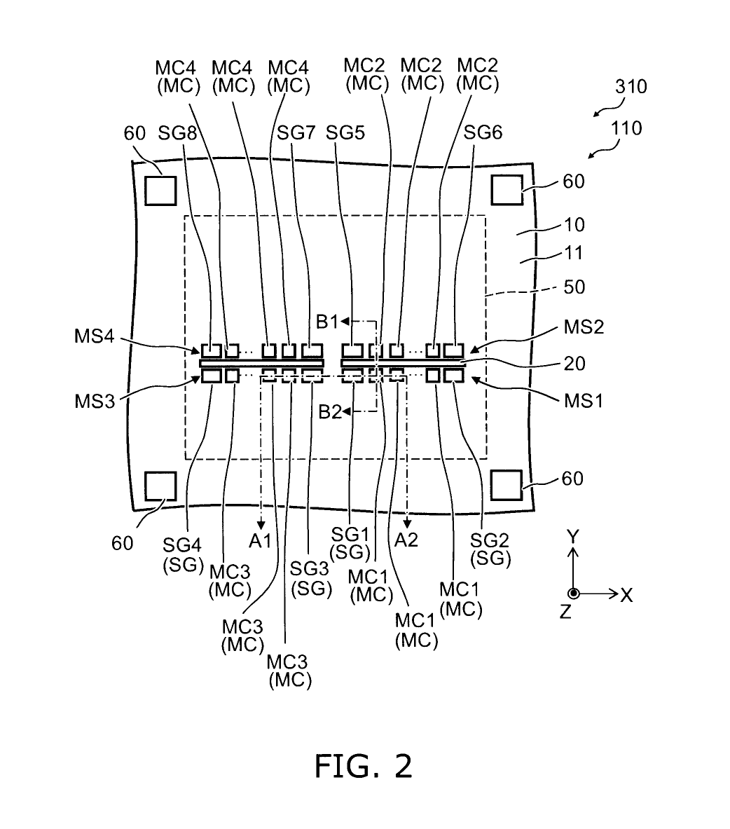

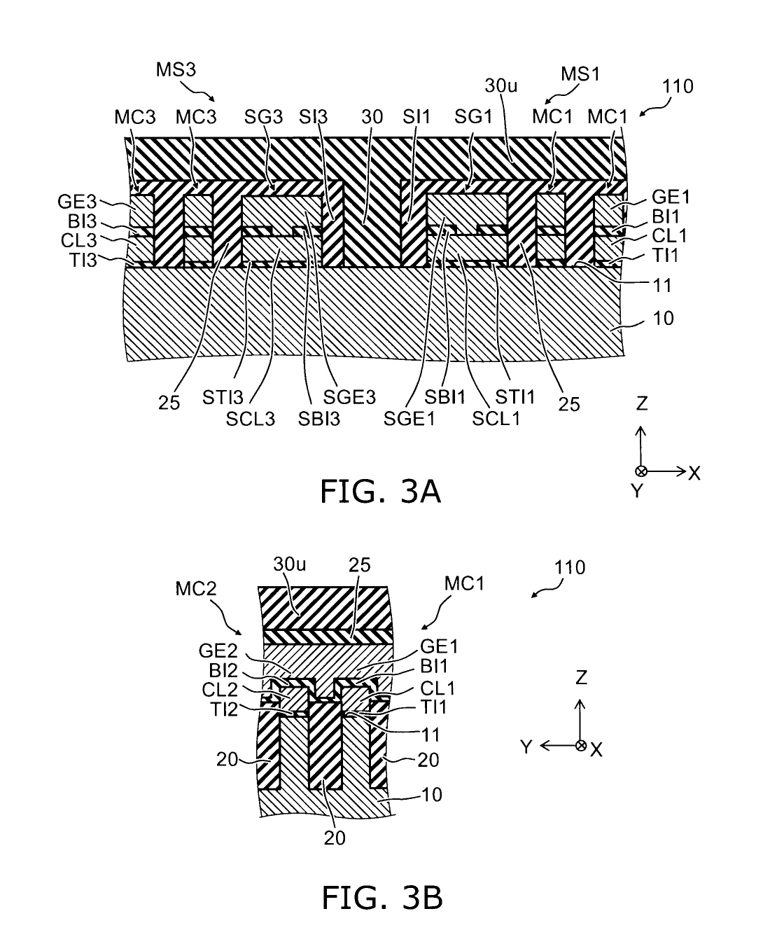

FIG. 2 is a schematic plan view illustrating the configuration of the semiconductor memory device according to the first embodiment. FIG. 3A and FIG. 3B are schematic cross-sectional views illustrating the configuration of a part of the semiconductor memory device according to the first embodiment.

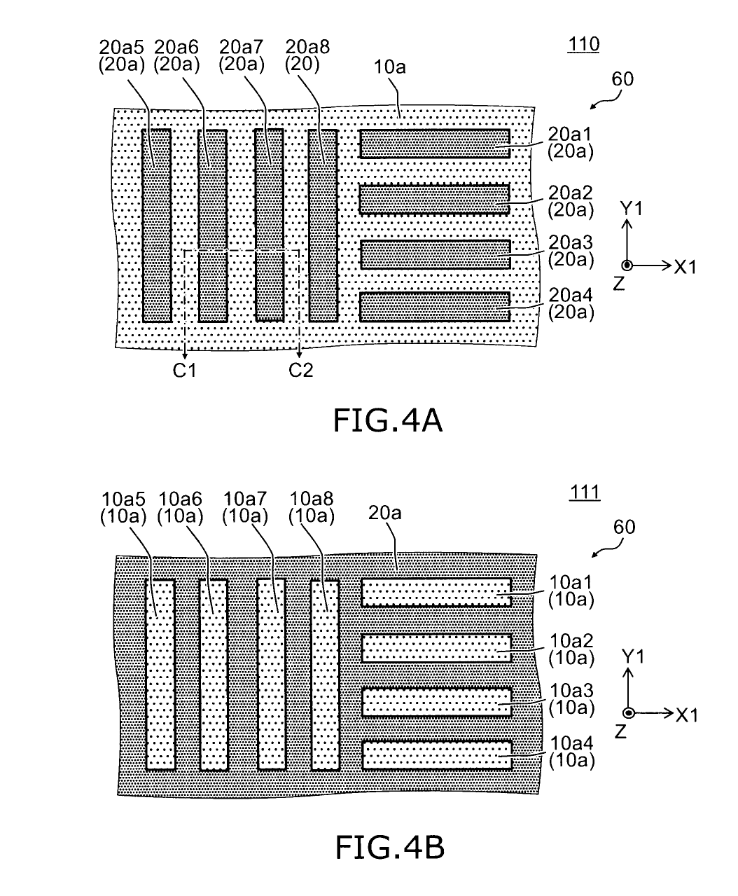

FIG. 4A and FIG. 4B are schematic plan views illustrating the configuration of a part of the semiconductor memory device according to the first embodiment.

First, an example of the semiconductor memory device according to the embodiment will be described with reference to FIG. 2.

As illustrated in FIG. 2, the semiconductor memory device 110 according to the embodiment includes a memory cell array unit 50 and an alignment mark unit 60. The alignment mark unit 60 is juxtaposed with the memory cell array unit 50.

As illustrated in FIG. 2, the semiconductor memory device 110 is a part of a wafer 310 during the manufacturing processes.

The memory cell array unit 50 and the alignment mark unit 60 are provided on a major surface 11 of a semiconductor layer 10. The semiconductor layer 10 is, for example, a semiconductor substrate. The semiconductor layer 10 includes, for example, a silicon substrate. However, the embodiment is not limited thereto. The semiconductor layer 10 may include, for example, a semiconductor film provided on an insulating layer. Hereinbelow, an example is described in which a silicon substrate is used as the semiconductor layer 10.

The memory cell array unit 50 includes a first memory string MS1, a second memory string MS2, and a device isolation insulating layer 20.

The first memory string MS1 is provided on the major surface 11 of the semiconductor layer 10. The second memory string MS2 is juxtaposed with the first memory string MS1 on the major surface 11. The device isolation insulating layer 20 partitions the first memory string MS1 and the second memory string MS2 from each other.

The alignment mark unit 60 includes a mark unit semiconductor layer (not illustrated) and a mark unit insulating layer (not illustrated). In the example illustrated in FIG. 2, the alignment mark unit 60 is provided around the memory cell array unit 50. There are four alignment mark units 60. However, the disposition and the number of the alignment mark units 60 are arbitrary. An example of the configuration of the alignment mark unit 60 is described below.

Herein, an axis perpendicular to the major surface 11 is taken as a Z-axis. One axis perpendicular to the Z-axis is taken as an X-axis. An axis perpendicular to the Z-axis and the X-axis is taken as a Y-axis.

In the specific example, the first memory string MS1 and the second memory string MS2 extend along the X-axis. At least a part of the device isolation insulating layer 20 extends along the X-axis.

The first memory string MS1 includes, for example, a first selection transistor SG1, a second selection transistor SG2, and multiple memory cells MC (multiple first memory cells MC1). The multiple first memory cells MC1 are provided between the first selection transistor SG1 and the second selection transistor SG2

The axis (the first axis) of the direction from the first selection transistor SG1 toward the second selection transistor SG2 is set to be the X-axis. However, the embodiment is not limited thereto. The first axis may be set to be any axis perpendicular to the Z-axis. Hereinbelow, the case is described where the first axis is the X-axis.

The multiple first memory cells MC1 are connected in series along the X-axis.

Similarly, the second memory string MS2 may include, for example, two selection transistors SG (a fifth selection transistor SG5 and a sixth selection transistor SG6) and multiple memory cells MC (multiple second memory cells MC2) provided therebetween. The multiple second memory cells MC2 are connected in series along the X-axis.

The second memory string MS2 is arranged with the first memory string MS1 along the Y-axis.

The memory cell array unit 50 may further include a third memory string.

The third memory string MS3 extends along the X-axis along an extension of the extension axis of the first memory string MS1.

The third memory string MS3 may include, for example, a third selection transistor SG3, a fourth selection transistor SG4, and multiple memory cells MC (multiple third memory cells MC3). The multiple third memory cells MC3 are provided between the third selection transistor SG3 and the fourth selection transistor SG4. The multiple third memory cells MC3 are connected in series along the X-axis.

The first selection transistor SG1 and the third selection transistor SG3 are disposed between the second selection transistor SG2 and the fourth selection transistor SG4.

The memory cell array unit 50 may further include a fourth memory string.

The fourth memory string MS4 is arranged with the second memory string MS2 along the X-axis. The fourth memory string MS4 is arranged with the third memory string MS3 along the Y-axis. The fourth memory string MS4 extends along the X-axis along an extension of the extension axis of the second memory string MS2.

The fourth memory string MS4 may include, for example, two selection transistors SG (a seventh selection transistor SG7 and an eighth selection transistor SG8) and multiple memory cells MC (multiple fourth memory cells MC4) provided therebetween. The multiple fourth memory cells MC4 are connected in series along the X-axis.

The fifth selection transistor SG5 and the seventh selection transistor SG7 are disposed between the sixth selection transistor SG6 and the eighth selection transistor SG8.

FIG. 3A is a cross-sectional view along line A1-A2 of FIG. 2. FIG. 3B is a cross-sectional view along line B1-B2 of FIG. 2.

As illustrated in FIG. 3A, each of the multiple first memory cells MC1 includes a charge retaining layer (a first charge retaining layer CL1).

In addition to the first charge retaining layer CL1, each of the multiple first memory cells MC1 may further include, for example, a gate electrode (a first gate electrode GE1), a tunneling insulating film (a first tunneling insulating film TI1), and a blocking insulating film (a first blocking insulating film BI1). The first gate electrode GE1 opposes the semiconductor layer 10. The first charge retaining layer CL1 is provided between the semiconductor layer 10 and the first gate electrode GE1. The first tunneling insulating film TI1 is provided between the semiconductor layer 10 and the first charge retaining layer CL1. The first blocking insulating film BI1 is provided between the first charge retaining layer CL1 and the first gate electrode GE1.

Similarly, each of the multiple third memory cells MC3 includes a third charge retaining layer CL3.

In addition to the third charge retaining layer CL3, each of the multiple third memory cells MC3 may further include, for example, a third gate electrode GE3, a third tunneling insulating film TI3, and a third blocking insulating film BI3. The third gate electrode GE3 opposes the semiconductor layer 10. The third charge retaining layer CL3 is provided between the semiconductor layer 10 and the third gate electrode GE3. The third tunneling insulating film TI3 is provided between the semiconductor layer 10 and the third charge retaining layer CL3. The third blocking insulating film BI3 is provided between the third charge retaining layer CL3 and the third gate electrode GE3.

As illustrated in FIG. 3B, each of the multiple second memory cells MC2 includes a second charge retaining layer CL2.

In addition to the second charge retaining layer CL2, each of the multiple second memory cells MC2 may further include, for example, a second gate electrode GE2, a second tunneling insulating film TI2, and a second blocking insulating film BI2. The second gate electrode GE2 opposes the semiconductor layer 10. The second charge retaining layer CL2 is provided between the semiconductor layer 10 and the second gate electrode GE2. The second tunneling insulating film TI2 is provided between the semiconductor layer 10 and the second charge retaining layer CL2. The second blocking insulating film BI2 is provided between the second charge retaining layer CL2 and the second gate electrode GE2.

Although not illustrated, each of the multiple fourth memory cells MC4 similarly includes a fourth charge retaining layer.

In addition to the fourth charge retaining layer, each of the multiple fourth memory cells MC4 may further include, for example, a fourth gate electrode, a fourth tunneling insulating film, and a fourth blocking insulating film. The fourth gate electrode opposes the semiconductor layer 10. The fourth charge retaining layer is provided between the semiconductor layer 10 and the fourth gate electrode. The fourth tunneling insulating film is provided between the semiconductor layer 10 and the fourth charge retaining layer. The fourth blocking insulating film is provided between the fourth charge retaining layer and the fourth gate electrode.

The charge retaining layers (the first charge retaining layer CL1, the second charge retaining layer CL2, the third charge retaining layer CL3, the fourth charge retaining layer, etc.) are, for example, conductive. The charge retaining layers may include, for example, polysilicon. In other words, the semiconductor memory device 110 is, for example, a floating-gate nonvolatile semiconductor memory device.

The gate electrodes (the first gate electrode GE1 to the fourth gate electrode, etc.) are, for example, conductive. The gate electrodes may include, for example, polysilicon. The tunneling insulating films (e.g., the first tunneling insulating film TI1 to the fourth tunneling insulating film, etc.) are, for example, insulative. The tunneling insulating films may include, for example, silicon oxide. The blocking insulating films (e.g., the first blocking insulating film BI1 to the fourth tunneling insulating film, etc.) are, for example, insulative. The blocking insulating films may include, for example, silicon oxide.

As illustrated in FIG. 3B, the first gate electrode GE1 is continuous from the second gate electrode GE2. The first gate electrode GE1 has a portion opposing at least a part of a side surface (a surface along the Z-axis) of the first charge retaining layer CL1. The second gate electrode GE2 has a portion opposing at least a part of a side surface (a surface along the Z-axis) of the second charge retaining layer CL2.

The first blocking insulating film BI1 is continuous from the second blocking insulating film BI2. The first blocking insulating film BI1 has a portion opposing at least a part of a side surface of the first charge retaining layer CL1. The second blocking insulating film BI2 has a portion opposing at least a part of a side surface of the second charge retaining layer CL2. The first blocking insulating film BI1 extends between a part of the side surface of the first charge retaining layer CL1 and a part of the first gate electrode GE1. The second blocking insulating film BI2 extends between a part of the side surface of the second charge retaining layer CL2 and a part of the second gate electrode GE2. The first blocking insulating film BI1 and the second blocking insulating film BI2 are, for example, IPD (Inter-poly Dielectric) films.

The device isolation insulating layer 20 partitions the first memory cell MC1 of the first memory string MS1 from the second memory cell MC2 of the second memory string MS2. Here, a direction of the major surface 11 side of the semiconductor layer 10 is defined as the direction of an upper direction. The upper surface of the device isolation insulating layer 20 is positioned between the upper surface of the first charge retaining layer CL1 and the lower surface of the first charge retaining layer CL1. In other words, a plane perpendicular to the Z-axis and including the upper surface of the device isolation insulating layer 20 is disposed between a plane perpendicular to the Z-axis and including the upper surface of the first charge retaining layer CL1 and a plane perpendicular to the Z-axis and including the lower surface of the first charge retaining layer CL1.

Although not illustrated, in the third memory cell MC3 and the fourth memory cell MC4, the configurations of the third gate electrode GE3 and the fourth gate electrode are similar to the configurations of the first gate electrode GE1 and the second gate electrode GE2; and the configurations of the third blocking insulating film BI3 and the fourth blocking insulating film are similar to the configurations of the first blocking insulating film BI1 and the second blocking insulating film BI2.

As illustrated in FIG. 3A, the first selection transistor SG1 may include, for example, a first selection unit charge retaining layer SCL1, a first selection unit gate electrode SGE1, a first selection unit tunneling insulating film STI1, and a first selection unit blocking insulating film SBI1. The first selection unit gate electrode SGE1 opposes the semiconductor layer 10. The first selection unit charge retaining layer SCL1 is provided between the semiconductor layer 10 and the first selection unit gate electrode SGE1. The first selection unit tunneling insulating film STI1 is provided between the semiconductor layer 10 and the first selection unit charge retaining layer SCL1. The first selection unit blocking insulating film SBI1 is provided between the first selection unit charge retaining layer SCL1 and the first selection unit gate electrode SGE1.

The first selection unit charge retaining layer SCL1 may include the material of the first charge retaining layer CL1. The first selection unit gate electrode SGE1 may include the material of the first gate electrode GE1. The first selection unit tunneling insulating film STI1 may include the material of the first tunneling insulating film TI1. The first selection unit blocking insulating film SBI1 may include the material of the first blocking insulating film BI1. An opening is provided in the first selection unit blocking insulating film SBI1; and the first selection unit gate electrode SGE1 is connected to the first selection unit charge retaining layer SCL1.

Similarly, the third selection transistor SG3 may include, for example, a third selection unit charge retaining layer SCL3, a third selection unit gate electrode SGE3, a third selection unit tunneling insulating film STI3, and a third selection unit blocking insulating film SBI3. The configurations thereof are similar to the configurations of the first selection unit charge retaining layer SCL1, the first selection unit gate electrode SGE1, the first selection unit tunneling insulating film STI1, and the first selection unit blocking insulating film SBI1 of the first selection transistor SG1; and a description therefore is omitted.

As illustrated in FIG. 3A and FIG. 3B, an inter-layer insulating film 25 is provided to cover the memory cells MC and the selection transistors. A filled insulating film 30 is provided to cover the inter-layer insulating film 25.

The inter-layer insulating film 25 may include, for example, silicon oxide.

The filled insulating film 30 may include, for example, coating-type silicon oxide. The filled insulating film 30 may include, for example, an insulating material including polysilazane, etc. However, the materials of the inter-layer insulating film 25 and the filled insulating film 30 are arbitrary.

Thus, in the semiconductor memory device 110, the first memory string MS1, the second memory string MS2, and the device isolation insulating layer 20 extend along the first axis (in this example, the X-axis) parallel to the major surface 11. The memory cell array unit 50 may further include the third memory string MS3 extending along the first axis (the X-axis) along an extension of the extension axis of the first memory string MS1 and the filled insulating film 30 having a portion filled between the first memory string MS1 and the third memory string MS3.

Specifically, at least a part of the filled insulating film 30 is filled between the first selection transistor SG1 and the third selection transistor SG3.

More specifically, the first memory string MS1 further includes a first side surface insulating layer SI1 provided on the side surface of the first selection transistor SG1 on the third selection transistor SG3 side. The first side surface insulating layer SI1 is a part of the inter-layer insulating film 25. The third memory string MS3 further includes a third side surface insulating layer SI3 provided on the side surface of the third selection transistor SG3 on the first selection transistor SG1 side. The third side surface insulating layer SI3 is a part of the inter-layer insulating film 25. At least a part of the filled insulating film 30 is filled between the first side surface insulating layer SI1 and the third side surface insulating layer SI3.

In this example, the filled insulating film 30 includes a portion filled between the first memory string MS1 and the third memory string MS3 and an upper insulating layer 30u that covers the inter-layer insulating film 25 on the first memory string MS1 and the third memory string MS3.

FIG. 4A and FIG. 4B illustrate an example of the alignment mark unit 60.

In the semiconductor memory device 110 as illustrated in FIG. 4A, the alignment mark unit 60 includes a continuous mark unit semiconductor layer 10a and multiple mark unit insulating layers 20a (e.g., first to eighth mark unit insulating layers 20a1 to 20a8, etc.). In this example, the first to fourth mark unit insulating layers 20a1 to 20a4 have band configurations extending along an X1-axis. The fifth to eighth mark unit insulating layers 20a5 to 20a8 have band configurations extending along a Y1-axis. The X1-axis is perpendicular to the Z-axis. The Y1-axis is perpendicular to the Z-axis and the X-axis. The X1-axis may be parallel to, perpendicular to, or tilted with respect to the X-axis and the Y-axis. In other words, the relationship between the X-axis and the X-axis and the relationship between the X1-axis and the Y-axis are arbitrary.

In the semiconductor memory device 111 as illustrated in FIG. 4B, the alignment mark unit 60 includes a continuous mark unit insulating layer 20a and multiple mark unit semiconductor layers 10a (e.g., first to eighth mark unit semiconductor layers 10a1 to 10a8, etc.). In this example, the first to fourth mark unit semiconductor layers 10a1 to 10a4 have band configurations extending along the X1-axis. The fifth to eighth mark unit semiconductor layers 10a5 to 10a8 have band configurations extending along the Y1-axis.

Thus, the configurations and the numbers of the mark unit semiconductor layers 10a and the mark unit insulating layers 20a of the alignment mark unit 60 are arbitrary. Also, multiple mark unit semiconductor layers 10a and multiple mark unit insulating layers 20a may be provided in one alignment mark unit 60.

The semiconductor memory device 110 will now be described.

FIG. 1 illustrates the configuration of the alignment mark unit 60 of the semiconductor memory device 110. Namely, FIG. 1 is a cross-sectional view along line C1-C2 of FIG. 4A.

As illustrated in FIG. 1, the mark unit insulating layer 20a is filled into the mark unit semiconductor layer 10a.

The mark unit semiconductor layer 10a is a part of the semiconductor layer 10. The semiconductor layer 10 of the region of the alignment mark unit 60 is used to form the mark unit semiconductor layer 10a. The mark unit semiconductor layer 10a is, for example, a silicon substrate. In other words, the mark unit semiconductor layer 10a includes the same material as the material of the semiconductor layer 10.

The mark unit insulating layer 20a is juxtaposed with the mark unit semiconductor layer 10a. The mark unit insulating layer 20a includes the same material as the material of the device isolation insulating layer 20. For example, at least a part of the mark unit insulating layer 20a is formed simultaneously with the device isolation insulating layer 20 when forming the device isolation insulating layer 20.

For example, the semiconductor layer 10 is a silicon substrate; and the material of the device isolation insulating layer 20 may include at least one selected from silicon oxide and silicon nitride. A high-quality semiconductor memory device can be manufactured stably.

In the semiconductor memory device 110 according to the embodiment as illustrated in FIG. 1, an upper surface 10u of the mark unit semiconductor layer 10a is included in a plane different from a plane including an upper surface 20u of the mark unit insulating layer 20a.

In other words, the upper surface 10u of the mark unit semiconductor layer 10a is disposed lower than the upper surface 20u of the mark unit insulating layer 20a. Or, the upper surface 10u of the mark unit semiconductor layer 10a is disposed higher than the upper surface 20u of the mark unit insulating layer 20a.

When performing mask alignment using the alignment mark unit 60, the mark unit semiconductor layer 10a and the mark unit insulating layer 20a are imaged. Then, the alignment mark is recognized based on the difference between the image of the mark unit semiconductor layer 10a and the image of the mark unit insulating layer 20a.

In the embodiment, the difference (e.g., the contrast) between the image of the mark unit semiconductor layer 10a and the image of the mark unit insulating layer 20a can be increased by disposing the upper surface 10u of the mark unit semiconductor layer 10a lower than or higher than the upper surface 20u of the mark unit insulating layer 20a.

Thereby, the alignment mark can be recognized easily. Thereby, the mask alignment precision can be increased. In particular, the effect of the alignment mark being easy to recognize is large in the case where the memory cells MC are downscaled and a high mask alignment precision is required. Misrecognition of the alignment mark can be suppressed; and productivity can be increased.

According to experiments of the inventor, the effect of suppressing the misrecognition of the alignment mark is increased by causing the difference in levels (a distance St along the Z-axis) from the upper surface 10u of the mark unit semiconductor layer 10a to the upper surface 20u of the mark unit insulating layer 20a to be not less than 40 nanometers (nm).

In the case where the difference in levels (the distance St along the Z-axis) from the upper surface 10u of the mark unit semiconductor layer 10a to the upper surface 20u of the mark unit insulating layer 20a is small, i.e., about 20 nm, there are cases where the difference (e.g., the contrast) between the image of the mark unit semiconductor layer 10a and the image of the mark unit insulating layer 20a is small. Therefore, there are cases where the suppression effect of the misrecognition of the alignment mark decreases.

Accordingly, in the embodiment, it is desirable for the distance St from a plane (a plane perpendicular to the Z-axis) parallel to the major surface 11 and including the upper surface 10u of the mark unit semiconductor layer 10a to a plane (a plane perpendicular to the Z-axis) parallel to the major surface 11 and including the upper surface 20u of the mark unit insulating layer 20a to be not less than 40 nm. The distance St may be determined by imaging the cross section of the semiconductor memory device using, for example, an electron microscope, etc.

In the specific example as illustrated in FIG. 1, the upper surface 10u of the mark unit semiconductor layer 10a is positioned lower than the upper surface 20u of the mark unit insulating layer 20a.

The alignment mark unit 60 further includes a mark unit filled insulating layer 30a provided on the mark unit insulating layer 20a, where the mark unit filled insulating layer 30a includes the same material as the filled insulating film 30.

In the specific example, a mark unit tunneling insulating film TIa is provided on the mark unit semiconductor layer 10a. A mark unit charge retaining layer CLa is provided on the mark unit tunneling insulating film TIa. The mark unit tunneling insulating film TIa may include, for example, the material of the first tunneling insulating film TI1. The mark unit charge retaining layer CLa may include, for example, the material of the first charge retaining layer CL1.

In the specific example, a first liner film 22a is provided to cover the mark unit insulating layer 20a and the mark unit charge retaining layer CLa. A second liner film 22b is provided to cover the first liner film 22a. The first liner film 22a may include, for example, a silicon oxide film by using TEOS. The second liner film 22b may include, for example, silicon nitride.

The upper surface of the second liner film 22b on the mark unit semiconductor layer 10a (on the mark unit charge retaining layer CLa) is positioned higher than the upper surface of the second liner film 22b on the mark unit insulating layer 20a. In other words, the mark unit filled insulating layer 30a is filled into the recess on the mark unit insulating layer 20a between the mark unit charge retaining layers CLa.

A first inter-layer insulating film 41 is provided on the mark unit filled insulating layer 30a and on the second liner film 22b. A second inter-layer insulating film 42 is provided on the first inter-layer insulating film 41. A cap insulating film 43 is provided on the second inter-layer insulating film 42. The first inter-layer insulating film 41 may include, for example, silicon oxide by using TEOS. The second inter-layer insulating film 42 may include, for example, silicon nitride. The cap insulating film 43 may include, for example, silicon oxide by using TEOS.

One example of a method for manufacturing the semiconductor memory device 110 will now be described.

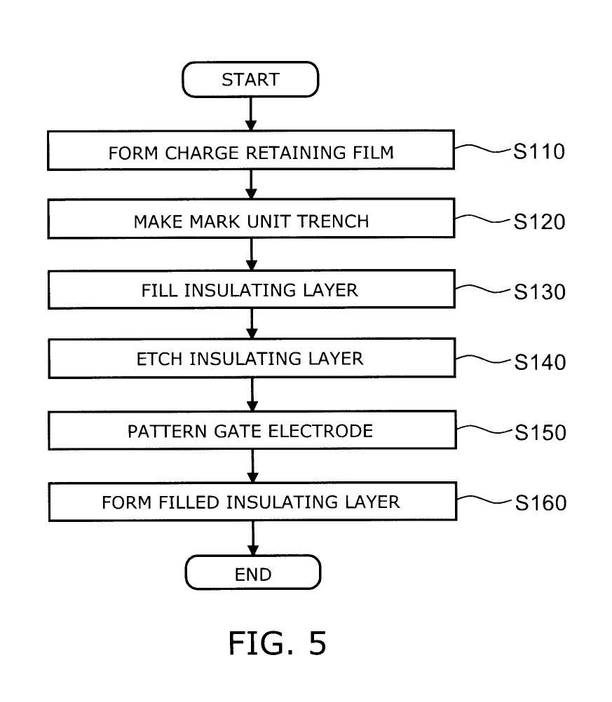

FIG. 5 is a flowchart illustrating the method for manufacturing the semiconductor memory device according to the first embodiment.

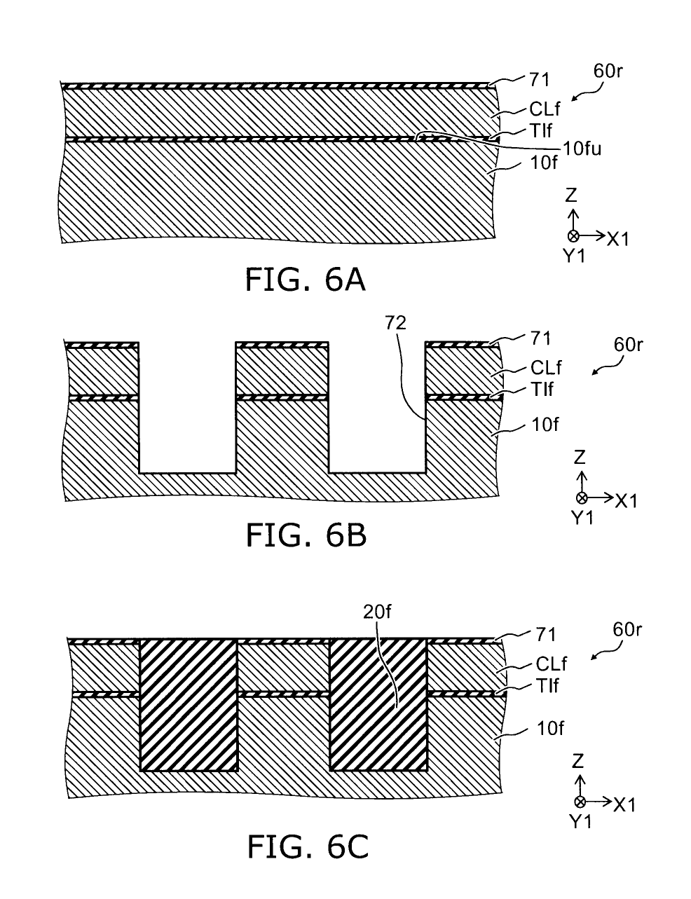

FIG. 6A to FIG. 6C are schematic cross-sectional views in order of the processes, illustrating the method for manufacturing the semiconductor memory device according to the first embodiment.

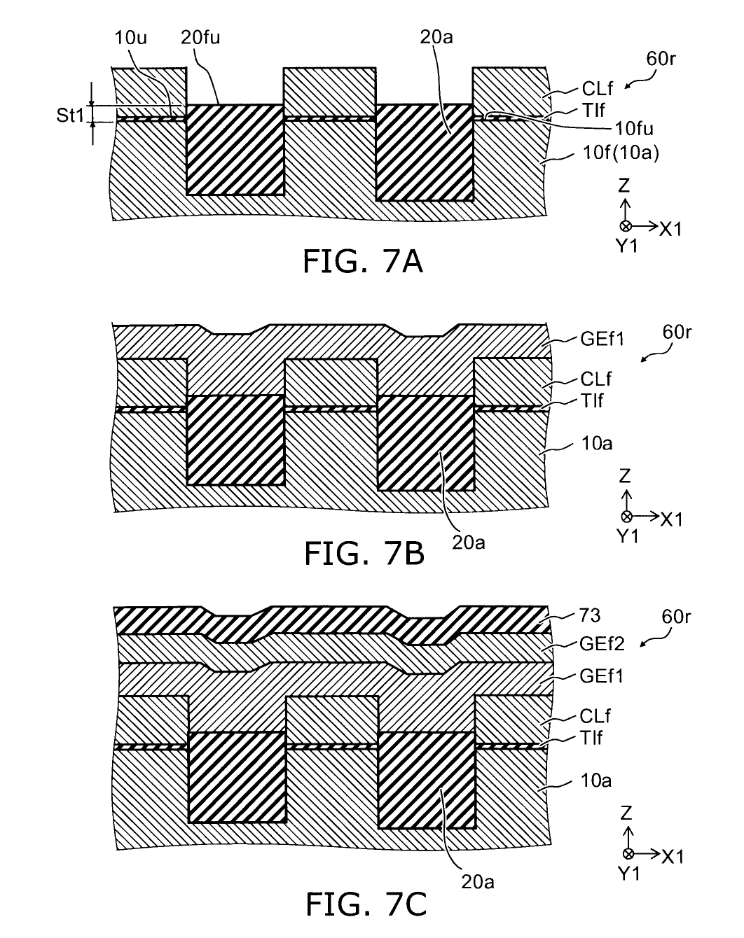

FIG. 7A to FIG. 7C are schematic cross-sectional views in order of the processes, illustrating the method for manufacturing the semiconductor memory device according to the first embodiment.

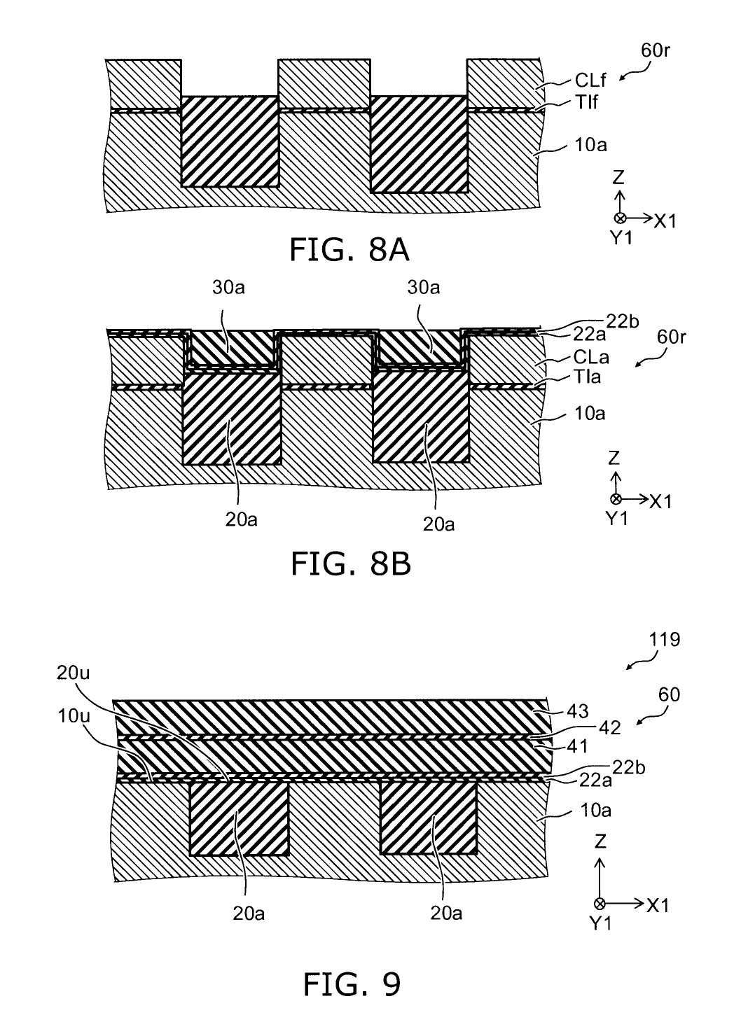

FIG. 8A and FIG. 8B are schematic cross-sectional views in order of the processes, illustrating the method for manufacturing the semiconductor memory device according to the first embodiment.

FIG. 6A to FIG. 8B are cross-sectional views related to the alignment mark unit 60.

The manufacturing method is a method for manufacturing a semiconductor memory device, where the device includes the memory cell array unit 50 and the alignment mark unit 60 juxtaposed with the memory cell array unit 50. The memory cell array unit 50 includes the first memory string MS1 provided on the major surface 11 of the semiconductor layer 10, the second memory string MS2 juxtaposed with the first memory string MS1 on the major surface 11, and the device isolation insulating layer 20 partitioning the first memory string MS1 and the second memory string MS2 from each other. The alignment mark unit 60 includes the mark unit semiconductor layer 10a, which is a part of the semiconductor layer 10, and the mark unit insulating layer 20a juxtaposed with the mark unit semiconductor layer 10a. The mark unit insulating layer 20a includes the same material as the material of the device isolation insulating layer 20. The upper surface 10u of the mark unit semiconductor layer 10a is included in a plane different from a plane including the upper surface 20u of the mark unit insulating layer 20a.

In the manufacturing method as illustrated in FIG. 5 and FIG. 6A, a charge retaining film CLf is formed in a base body upper surface 10fu of a mark unit region 60r of a base body 10f (step S110). The base body 10f is used to form the semiconductor layer 10 and the mark unit semiconductor layer 10a. The mark unit region 60r is the region where the alignment mark unit 60 of the base body 10f is formed. The charge retaining film CLf is a film used to form the charge retaining layers (the first charge retaining layers CL1) included in the memory cells MC (the first memory cells) included in the first memory string MS1 and the charge retaining layers (the second charge retaining layers CL2) included in the memory cells MC (the second memory cells MC2) included in the second memory string MS2.

Specifically, a tunneling-film insulating film TIf is formed on the base body upper surface 10fu. The tunneling-film insulating film TIf is a film used to form the tunneling insulating films (e.g., the first tunneling insulating film TI1, the second tunneling insulating film TI2, etc.). Then, the charge retaining film CLf is formed on the tunneling-film insulating film TIf.

Then, a silicon nitride film 71 is formed on the charge retaining film CLf for protection.

As illustrated in FIG. 5 and FIG. 6B, a mark unit trench 72 into which the mark unit insulating layer 20a is filled is made in the charge retaining film CLf and the base body 10f (step S120).

Simultaneously with the making of the mark unit trench 72, for example, a trench into which the device isolation insulating layer 20 is filled is made in the memory cell array unit 50.

As illustrated in FIG. 5 and FIG. 6C, an insulating layer 20f is filled into the mark unit trench 72 (step S130). The insulating layer 20f is used to form at least a part of the mark unit insulating layer 20a.

As illustrated in FIG. 5 and FIG. 7A, an upper surface 20fu of the insulating layer 20f is caused to be positioned lower than the charge retaining film CLf and higher than the base body upper surface 10fu by etching the insulating layer 20f filled into the mark unit trench 72 (step S140).

In other words, the upper surface 20fu of the insulating layer 20f is higher than the base body upper surface 10fu. The insulating layer 20f after the etching is used to form the mark unit insulating layer 20a. The base body 10f is used to form the mark unit semiconductor layer 10a. The base body upper surface 10fu is used to form the upper surface 10u of the mark unit semiconductor layer 10a.

Thus, the manufacturing method includes a process of forming a difference in levels by causing the upper surface 20fu of the insulating layer 20f filled into the mark unit trench 72 to be included in a plane different from a plane including the base body upper surface 10fu of the base body 10f of the mark unit region 60r by etching at least one selected from the insulating layer 20f filled into the mark unit trench 72 and the base body upper surface 10fu of the base body 10f of the mark unit region 60r.

Thereby, the semiconductor memory device 110 is manufactured with a configuration in which the upper surface 10u of the mark unit semiconductor layer 10a is included in a plane different from a plane including the upper surface 20u of the mark unit insulating layer 20a.

A distance St1 along the Z-axis from the upper surface 20fu of the insulating layer 20f to the base body upper surface 10fu corresponds to the difference in levels (the distance St along the Z-axis) from the upper surface 10u of the mark unit semiconductor layer 10a to the upper surface 20u of the mark unit insulating layer 20a. It is desirable for the distance St1 along the Z-axis from the upper surface 20fu of the insulating layer 20f to the base body upper surface 10fu to be not less than 40 nm.

As illustrated in FIG. 5, the manufacturing method may further include patterning the gate electrodes (the first gate electrodes GE1) included in the memory cells MC (the first memory cells MC1) included in the first memory string MS1 and the gate electrodes (the second gate electrodes GE2) included in the memory cells MC (the second memory cells MC2) included in the second memory string MS2 (step S150).

For example, as illustrated in FIG. 7B, a gate-electrode first conductive layer GEf1 is formed on the mark unit insulating layer 20a and on the charge retaining film CLf. Although not illustrated, the gate-electrode first conductive layer GEf1 is formed also in the memory cell array unit 50.

As illustrated in FIG. 7C, a gate-electrode second conductive layer GEf2 is formed on the gate-electrode first conductive layer GEf1. A cap layer 73 is formed on the gate-electrode second conductive layer GEf2. Although not illustrated, the gate-electrode second conductive layer GEf2 and the cap layer 73 are formed also in the memory cell array unit 50.

The gate-electrode first conductive layer GEf1 and the gate-electrode second conductive layer GEf2 may include, for example, polysilicon. The cap layer 73 may include, for example, silicon nitride.

Then, although not illustrated, the gate electrodes (e.g., the first gate electrode GE1, the second gate electrode GE2, etc.) of the memory cell array unit 50 are patterned. In other words, step S150 is implemented.

Thereby, as illustrated in FIG. 8A, the gate-electrode first conductive layer GEf1, the gate-electrode second conductive layer GEf2, and the cap layer 73 are removed in the alignment mark unit 60 (the mark unit region 60r).

Then, as illustrated in FIG. 5, the manufacturing method may further include forming the mark unit filled insulating layer 30a on the insulating layer 20f (the mark unit insulating layer 20a) which is recessed lower than the charge retaining film CLf by performing etching after the filling into the mark unit trench 72 (step S160).

For example, as illustrated in FIG. 8B, the first liner film 22a is formed to cover the insulating layer 20f (the mark unit insulating layer 20a) and the charge retaining film CLf. The second liner film 22b is formed on the first liner film 22a. The mark unit filled insulating layer 30a is formed on the second liner film 22b. The mark unit filled insulating layer 30a is filled into the recess between the charge retaining films CLf (on the mark unit insulating layer 20a). Then, the upper surface is planarized if necessary.

Although not illustrated, the formation of the mark unit filled insulating layer 30a is performed simultaneously with, for example, the formation of the filled insulating film 30 of the memory cell array unit 50.

The first inter-layer insulating film 41 is formed on the mark unit filled insulating layer 30a and the second liner film 22b. Then, the second inter-layer insulating film 42 is formed on the first inter-layer insulating film 41. Then, the cap insulating film 43 is formed on the second inter-layer insulating film 42.

Thereby, the alignment mark unit 60 illustrated in FIG. 1 is formed. According to the manufacturing method, the semiconductor memory device 110 in which the upper surface 10u of the mark unit semiconductor layer 10a is disposed lower than the upper surface 20u of the mark unit insulating layer 20a can be manufactured with high productivity. According to the manufacturing method, the alignment mark can be recognized easily; and the mask alignment precision can be increased. Misrecognition of the alignment mark can be suppressed; and productivity can be increased.

FIG. 9 is a schematic cross-sectional view illustrating the configuration of a part of a semiconductor memory device of a first reference example.

Namely, this drawing illustrates the configuration of the alignment mark unit 60 of the semiconductor memory device 119 of the first reference example.

In the first reference example as illustrated in FIG. 9, the upper surface 10u of the mark unit semiconductor layer 10a is included in the same plane as a plane including the upper surface 20u of the mark unit insulating layer 20a. In other words, the upper surface 20u and the upper surface 10u are disposed in substantially the same plane. Therefore, the difference (e.g., the contrast) between the image of the mark unit semiconductor layer 10a and the image of the mark unit insulating layer 20a is small. Therefore, the alignment mark is difficult to recognize. Therefore, it is difficult to improve the mask alignment precision. Also, misrecognition of the alignment mark occurs easily; and productivity is low.

The memory cell array unit 50 has a configuration in which a difference in levels is provided from the upper surface of the semiconductor layer 10 to the upper surface of the device isolation insulating layer 20.

For example, in the memory cell array unit 50 of the semiconductor memory device 110 according to the embodiment as illustrated in FIG. 3B as well, the upper surface of the device isolation insulating layer 20 is disposed higher than the upper surface of the semiconductor layer 10.

For example, in the semiconductor memory device 119 of the first reference example illustrated in FIG. 9 as well, although the upper surface of the device isolation insulating layer 20 is disposed higher than the upper surface of the semiconductor layer 10, the upper surface 10u of the mark unit semiconductor layer 10a is included in the plane including the upper surface 20u of the mark unit insulating layer 20a. Therefore, as recited above, the alignment mark is difficult to recognize.

In the embodiment, the alignment mark is easy to recognize because the upper surface 10u of the mark unit semiconductor layer 10a is disposed inside a plane different from the plane including the upper surface 20u of the mark unit insulating layer 20a.

### Second Embodiment

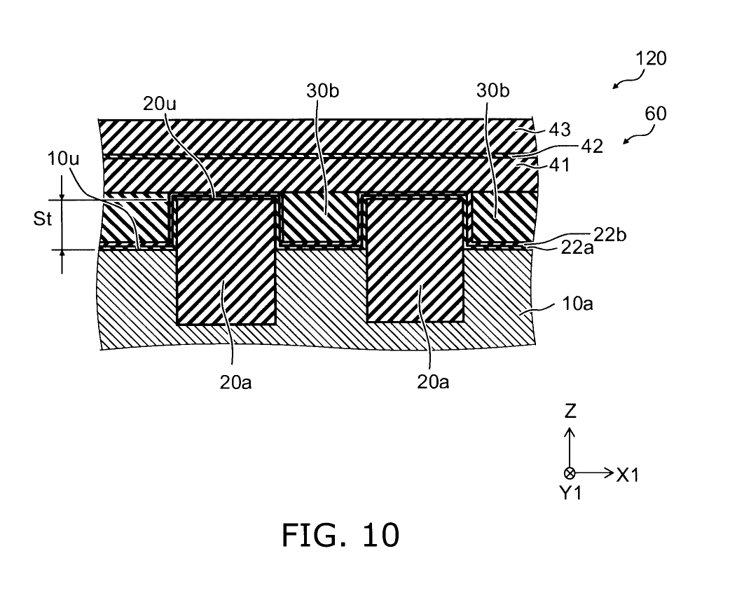

FIG. 10 is a schematic cross-sectional view illustrating the configuration of a part of a semiconductor memory device according to a second embodiment.

Namely, this drawing illustrates an example of the configuration of the alignment mark unit 60 of the semiconductor memory device 120 according to the embodiment.

The configuration of the memory cell array unit 50 of the semiconductor memory device 120 may be similar to that of the semiconductor memory device 110, and a description is omitted. The planar configuration of the alignment mark unit 60 of the semiconductor memory device 120 may be similar to that of the semiconductor memory device 110, and a description is omitted. The cross-sectional configuration of the alignment mark unit 60 of the semiconductor memory device 120 will now be described.

FIG. 10 is a cross-sectional view corresponding to a cross section along line C1-C2 of FIG. 4A.

In the semiconductor memory device 120 as illustrated in FIG. 10 as well, the mark unit insulating layer 20a is filled into the mark unit semiconductor layer 10a.

The mark unit semiconductor layer 10a is a part of the semiconductor layer 10.

The mark unit insulating layer 20a is juxtaposed with the mark unit semiconductor layer 10a. The mark unit insulating layer 20a includes the same material as the material of the device isolation insulating layer 20.

In the semiconductor memory device 120 as illustrated in FIG. 10 as well, the upper surface 10u of the mark unit semiconductor layer 10a is included in a plane different from the plane including the upper surface 20u of the mark unit insulating layer 20a.

In the specific example, the upper surface 10u of the mark unit semiconductor layer 10a is disposed lower than the upper surface 20u of the mark unit insulating layer 20a. Thereby, the difference (e.g., the contrast) between the image of the mark unit semiconductor layer 10a and the image of the mark unit insulating layer 20a can be increased during the mask alignment.

Thereby, the alignment mark can be recognized easily; and the mask alignment precision can be increased. Also, misrecognition of the alignment mark can be suppressed; and productivity can be increased.

In such a case as well, it is desirable for the distance St from a plane (a plane perpendicular to the Z-axis) parallel to the major surface 11 and including the upper surface 10u of the mark unit semiconductor layer 10a to a plane (a plane perpendicular to the Z-axis) parallel to the major surface 11 and including the upper surface 20u of the mark unit insulating layer 20a to be not less than 40 nm.

In the semiconductor memory device 120, the difference in levels (the distance St) from the upper surface 10u of the mark unit semiconductor layer 10a to the upper surface 20u of the mark unit insulating layer 20a in the alignment mark unit 60 is larger than the difference in levels from the upper surface of the semiconductor layer 10 to the upper surface of the device isolation insulating layer 20 in the memory cell MC of the memory cell array unit 50.

In the semiconductor memory device 120, the alignment mark unit 60 further includes a mark unit filled insulating layer 30b provided on the mark unit semiconductor layer 10a, where the mark unit filled insulating layer 30b includes the same material as that of the filled insulating film 30.

In the specific example, the first liner film 22a is provided to cover the mark unit insulating layer 20a and the mark unit semiconductor layer 10a. The second liner film 22b is provided to cover the first liner film 22a. The first liner film 22a may include, for example, a silicon oxide film by using TEOS. The second liner film 22b may include, for example, silicon nitride.

The upper surface of the second liner film 22b on the mark unit insulating layer 20a is positioned higher than the upper surface of the second liner film 22b on the mark unit semiconductor layer 10a. In other words, the mark unit filled insulating layer 30b is filled into the recess on the mark unit semiconductor layer 10a between the mark unit insulating layers 20a.

The first inter-layer insulating film 41 is provided on the mark unit filled insulating layer 30a and on the second liner film 22b. The second inter-layer insulating film 42 is provided on the first inter-layer insulating film 41. The cap insulating film 43 is provided on the second inter-layer insulating film 42.

One example of a method for manufacturing the semiconductor memory device 120 will now be described.

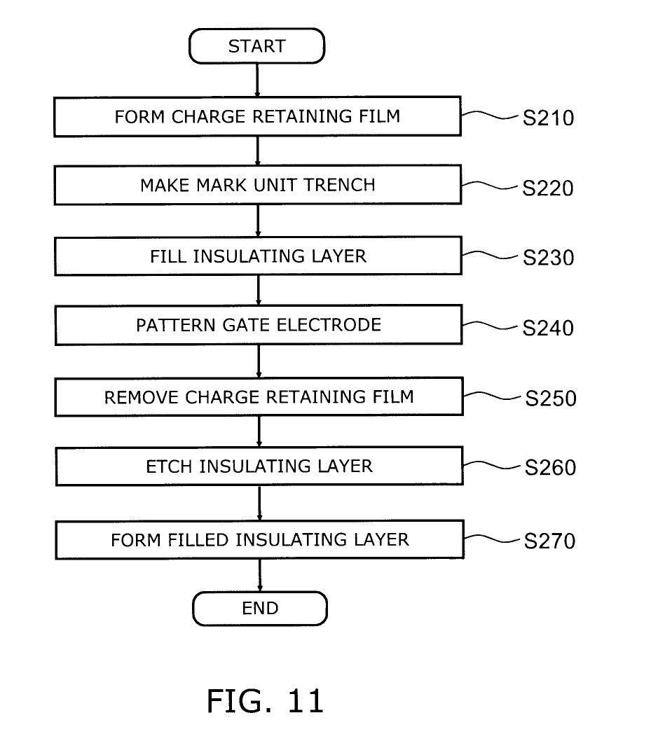

FIG. 11 is a flowchart illustrating the method for manufacturing the semiconductor memory device according to the second embodiment.

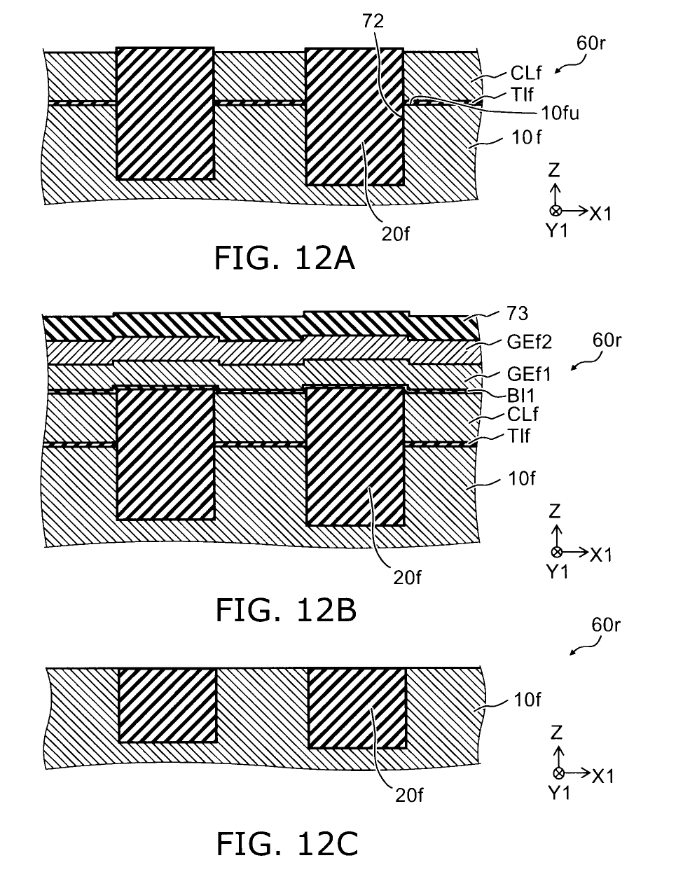

FIG. 12A to FIG. 12C are schematic cross-sectional views in order of the processes, illustrating the method for manufacturing the semiconductor memory device according to the second embodiment.

FIG. 13A and FIG. 13B are schematic cross-sectional views in order of the processes, illustrating the method for manufacturing the semiconductor memory device according to the second embodiment.

FIG. 12A to FIG. 13B are cross-sectional views related to the alignment mark unit 60.

As illustrated in FIG. 11 and FIG. 12A, the charge retaining film CLf used to form the charge retaining layers (the first charge retaining layers CL1) included in the memory cells MC (the first memory cells MC1) included in the first memory string MS1 and the charge retaining layers (the second charge retaining layers CL2) included in the memory cells MC (the second memory cells MC2) included in the second memory string MS2 is formed on the base body upper surface 10fu of the mark unit region 60r of the base body 10f used to form the semiconductor layer 10 and the mark unit semiconductor layer 10a where the alignment mark unit 60 is formed (step S210).

Specifically, the tunneling-film insulating film TIf used to form the tunneling insulating films (e.g., the first tunneling insulating film TI1, the second tunneling insulating film TI2, etc.) is formed on the base body upper surface 10fu. Then, the charge retaining film CLf is formed on the tunneling-film insulating film TIf.

Continuing as illustrated in FIG. 11 and FIG. 12A, the mark unit trench 72 into which the mark unit insulating layer 20a is filled is made in the charge retaining film CLf and the base body 10f (step S220).

Then, as illustrated in FIG. 11 and FIG. 12A, the insulating layer 20f is filled into the mark unit trench 72 (step S230).

As illustrated in FIG. 11, the gate electrodes (the first gate electrodes GE1) included in the memory cells MC (the first memory cells MC1) included in the first memory string MS1 and the gate electrodes (the second gate electrodes GE2) included in the memory cells MC (the second memory cells MC2) included in the second memory string MS2 are patterned (step S240); and the charge retaining film CLf formed in the mark unit region 60r is removed (step S250). For example, step S250 can be implemented simultaneously with step S240.

Specifically, as illustrated in FIG. 12B, the gate-electrode first conductive layer GEf1 is formed on the insulating layer 20f filled into the mark unit trench 72 and on the charge retaining film CLf. Although not illustrated, the gate-electrode first conductive layer GEf1 is formed also in the memory cell array unit 50.

Then, the gate-electrode second conductive layer GEf2 is formed on the gate-electrode first conductive layer GEf1. The cap layer 73 is formed on the gate-electrode second conductive layer GEf2. Although not illustrated, the gate-electrode second conductive layer GEf2 and the cap layer 73 are formed also in the memory cell array unit 50.

The gate-electrode first conductive layer GEf1 and the gate-electrode second conductive layer GEf2 may include, for example, polysilicon. The cap layer 73 may include, for example, silicon nitride.

Then, although not illustrated, the gate electrodes (e.g., the first gate electrode GE1, the second gate electrode GE2, etc.) of the memory cell array unit 50 are patterned. In other words, step S240 is implemented.

At this time, as illustrated in FIG. 12C, the tunneling-film insulating film TIf, the charge retaining film CLf, the gate-electrode first conductive layer GEf1, the gate-electrode second conductive layer GEf2, and the cap layer 73 of the alignment mark unit 60 (the mark unit region 60r) are removed (step S250). In other words, step S250 is implemented.

As illustrated in FIG. 11 and FIG. 13A, the base body upper surface 10fu of the base body 10f of the mark unit region 60r exposed by the removal of the charge retaining film CLf is etched (step S260); and the base body upper surface 10fu is caused to be lower than the insulating layer 20f filled into the mark unit trench 72.

The base body 10f in which the base body upper surface 10fu is etched is used to form the mark unit semiconductor layer 10a. The insulating layer 20f filled into the mark unit trench 72 is used to form the mark unit insulating layer 20a.

Thereby, the upper surface 10u of the mark unit semiconductor layer 10a is positioned lower than the upper surface 20u of the mark unit insulating layer 20a.

As illustrated in FIG. 11, the manufacturing method may further include forming the mark unit filled insulating layer 30b on the etched base body 10f (the mark unit semiconductor layer 10a).

Specifically, as illustrated in FIG. 13B, the first liner film 22a is formed to cover the mark unit semiconductor layer 10a and the mark unit insulating layer 20a. Then, the second liner film 22b is formed on the first liner film 22a. Then, the mark unit filled insulating layer 30b is formed on the second liner film 22b. The mark unit filled insulating layer 30b is filled into the recess between the mark unit insulating layers 20a (on the mark unit semiconductor layer 10a). Then, the upper surface is planarized if necessary.

Continuing, the first inter-layer insulating film 41 is formed on the mark unit filled insulating layer 30b and the second liner film 22b. Then, the second inter-layer insulating film 42 is formed on the first inter-layer insulating film 41. The cap insulating film 43 is formed on the second inter-layer insulating film 42.

Thereby, the alignment mark unit 60 illustrated in FIG. 10 is formed. According to the manufacturing method, the semiconductor memory device 120 in which the upper surface 10u of the mark unit semiconductor layer 10a is disposed lower than the upper surface 20u of the mark unit insulating layer 20a can be manufactured with high productivity. According to the manufacturing method, the alignment mark can be recognized easily; and the mask alignment precision can be increased. Further, misrecognition of the alignment mark can be suppressed; and productivity can be increased.

FIG. 14 is a schematic cross-sectional view illustrating another method for manufacturing the semiconductor memory device according to the embodiment.

FIG. 14 illustrates the process after the process illustrated in FIG. 12B.

In this manufacturing method as illustrated in FIG. 14, the gate-electrode first conductive layer GEf1, the gate-electrode second conductive layer GEf2, and the cap layer 73 are formed sequentially on the insulating layer 20f filled into the mark unit trench 72 and on the charge retaining film CLf; and the insulating layer 20f is exposed by etching the gate-electrode first conductive layer GEf1, the gate-electrode second conductive layer GEf2, and the cap layer 73. Then, the upper surface (the upper surface 20u) of the insulating layer 20f is positioned lower than the charge retaining film CLf and higher than the base body upper surface 10fu (the upper surface 10u).

By this method as well, the upper surface 10u of the mark unit semiconductor layer 10a is positioned lower than the upper surface 20u of the mark unit insulating layer 20a.

However, in this method, there are cases where, for example, a part (a polysilicon film) of at least one selected from the gate-electrode first conductive layer GEf1 and the gate-electrode second conductive layer GEf2 remains on the insulating layer 20f in the etching recited above. Therefore, as described in regard to FIG. 12B to FIG. 13A, it is more desirable for the base body upper surface 10fu of the base body 10f of the mark unit region 60r to be etched (step S260) after the tunneling-film insulating film TIf, the charge retaining film CLf, the gate-electrode first conductive layer GEf1, the gate-electrode second conductive layer GEf2, and the cap layer 73 of the alignment mark unit 60 (the mark unit region 60r) are removed (step S250).

In the manufacturing method illustrated in FIG. 5 and FIG. 11, the contrast of the alignment mark is enhanced while suppressing the occurrence of the polysilicon film residue without increasing the number of processes. Thereby, the misrecognition (the misdetection) of the alignment mark can be improved.

Although the upper surface 10u of the mark unit semiconductor layer 10a is positioned lower than the upper surface 20u of the mark unit insulating layer 20a in the example recited above, the embodiment is not limited thereto. The upper surface 10u of the mark unit semiconductor layer 10a may be positioned higher than the upper surface 20u of the mark unit insulating layer 20a.

Although the examples recited above illustrates the case where the charge retaining layer is conductive (e.g., polysilicon), the embodiment is not limited thereto.

The charge retaining layer may be insulative. In such a case, for example, the blocking insulating film can be omitted. For example, each of the multiple first memory cells MC1 may include the first gate electrode GE1 opposing the semiconductor layer 10, an insulative first charge retaining layer CL1 provided between the semiconductor layer 10 and the first gate electrode GE1, and the first tunneling insulating film TI1 provided between the semiconductor layer 10 and the first charge retaining layer CL1.

Each of the multiple first memory cells MC1 may further include the first blocking insulating film BI1 provided between the insulative first charge retaining layer CL1 and the first gate electrode GE1.

The insulative charge retaining layer (e.g., the first charge retaining layer CL1) may include silicon nitride.

Thus, the semiconductor memory device according to the embodiment also can have a MNOS structure or a MONOS structure.

The embodiment may include the wafer 310 illustrated in FIG. 2.

As illustrated in FIG. 2, the wafer 310 according to the embodiment includes the memory cell array unit 50 and the alignment mark unit 60.

The memory cell array unit 50 includes the first memory string MS1 provided on the major surface 11 of the semiconductor layer 10, the second memory string MS2 juxtaposed with the first memory string MS1 on the major surface 11, and the device isolation insulating layer 20 partitioning the first memory string MS1 and the second memory string MS2 from each other.

The alignment mark unit 60 is juxtaposed with the memory cell array unit 50.

The alignment mark unit 60 includes the mark unit semiconductor layer 10a, which is a part of the semiconductor layer 10, and the mark unit insulating layer 20a juxtaposed with the mark unit semiconductor layer 10a, where the mark unit insulating layer 20a includes the same material as the material of the device isolation insulating layer 20.

In the wafer 310 according to the embodiment, the upper surface of the mark unit semiconductor layer 10a is included in a plane different from the plane including the upper surface of the mark unit insulating layer 20a.

The alignment mark unit 60 of the wafer 310 according to the embodiment may have, for example, a configuration similar to the configurations illustrated in FIG. 1, FIG. 3A, FIG. 3B, FIG. 10, etc. Methods similar to the methods described in regard to FIG. 5 and FIG. 11 can be applied to the method for manufacturing the wafer 310.

According to the wafer of the embodiment, a wafer can be provided in which the alignment mark is recognized easily and the mask alignment precision is improved.

According to the embodiment, a semiconductor memory device, a semiconductor wafer, and a method for manufacturing a semiconductor memory device can be provided in which the alignment mark is recognized easily and the mask alignment precision is improved.

### Third Embodiment

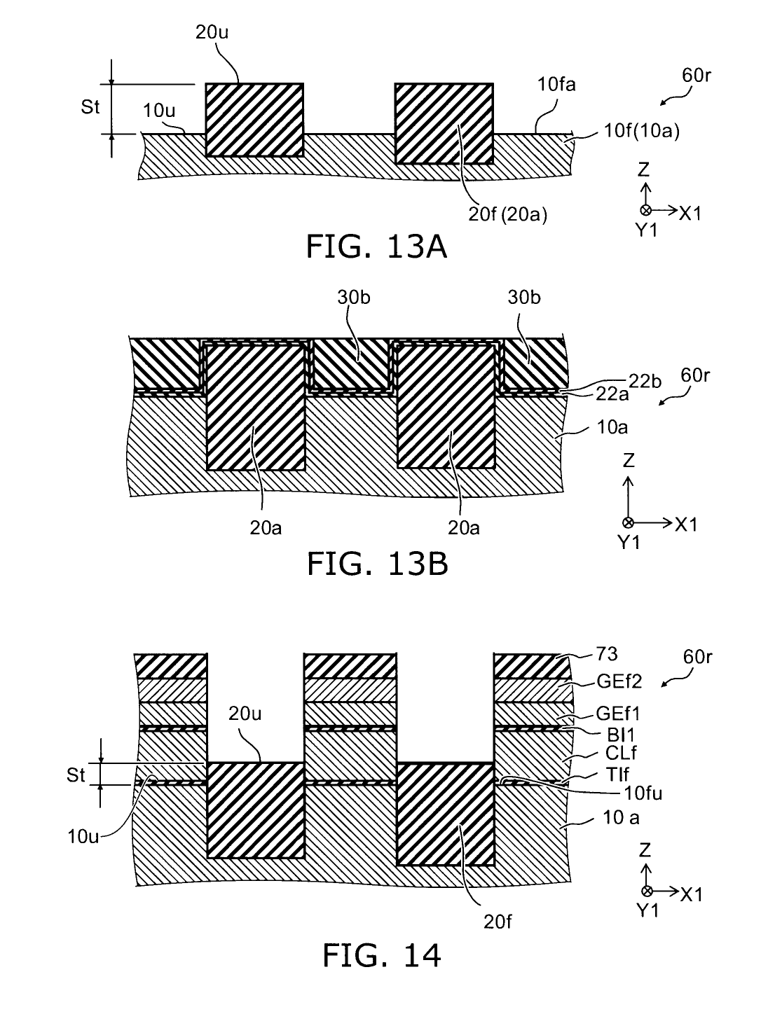

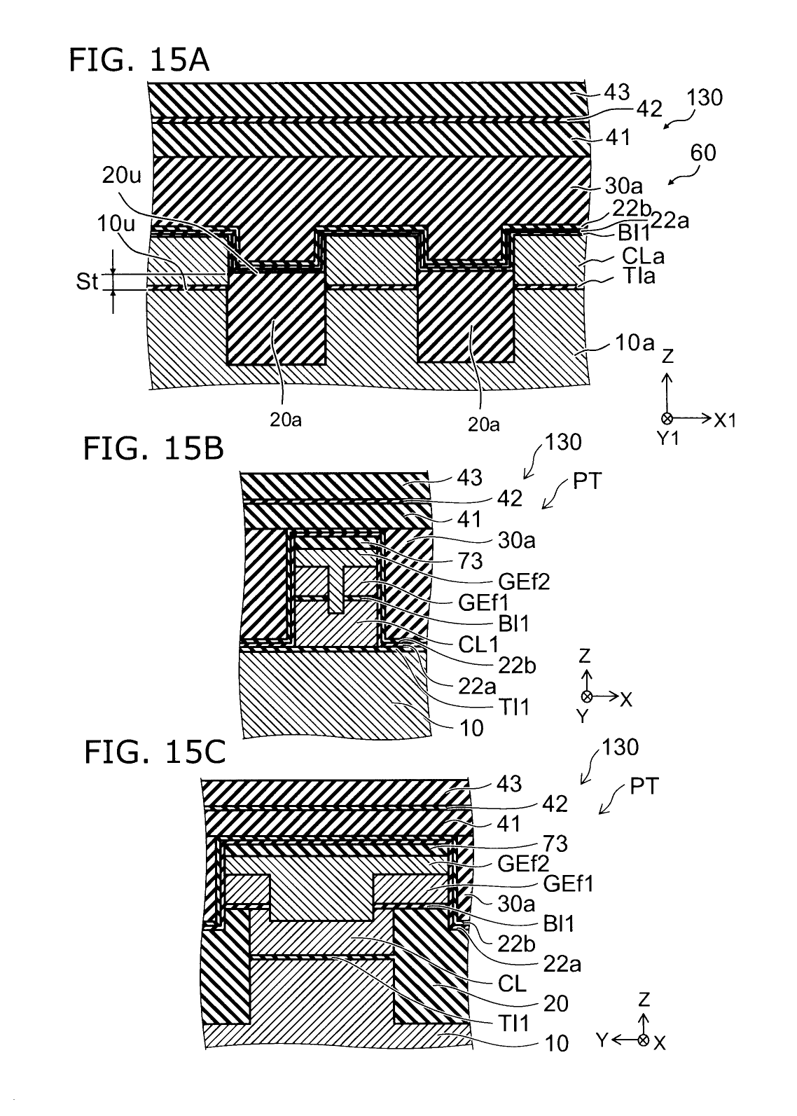

FIGS. 15A to 15C are schematic cross-sectional views illustrating the configuration of a part of a semiconductor memory device according to a third embodiment.

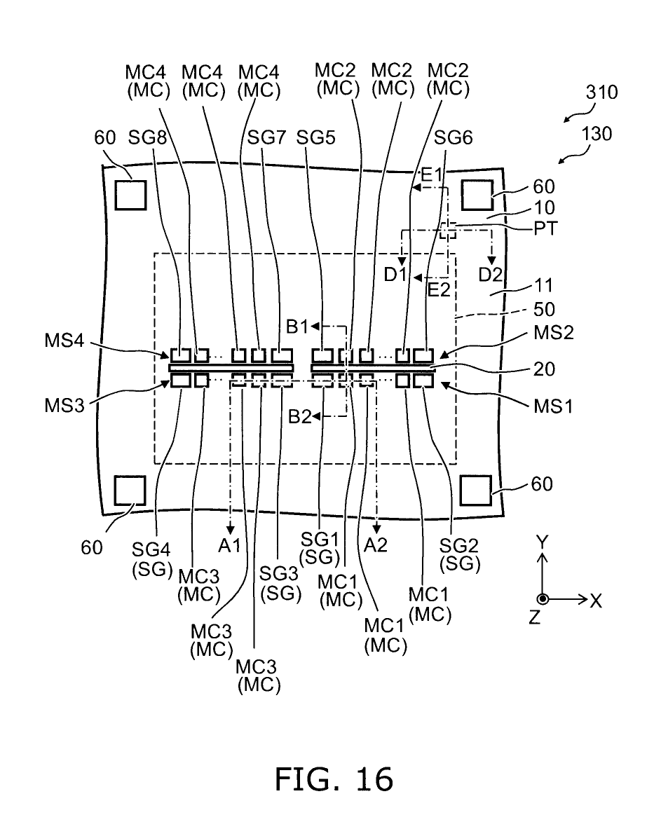

FIG. 16 is a schematic plan view illustrating the configuration of the semiconductor memory device according to the third embodiment.

First, an example of the semiconductor memory device according to the embodiment will be described with reference to FIG. 16.

As illustrated in FIG. 16, the semiconductor memory device 130 according to the embodiment includes a memory cell array unit 50, an alignment mark unit 60, and a peripheral transistor PT. The alignment mark unit 60 is juxtaposed with the memory cell array unit 50. The peripheral transistor PT is provided on a peripheral part of the memory cell array unit 50 more inner side than the alignment mark unit 60. The configuration of the memory cell array unit 50 of the semiconductor memory device 130 may be similar to that of the semiconductor memory device 110 described above, and a detailed description is omitted.

As illustrated in FIG. 16, the semiconductor memory device 130 is a part of a wafer 320 during the manufacturing processes.

The memory cell array unit 50, the alignment mark unit 60, and the peripheral transistor PT are provided on a major surface 11 of a semiconductor layer 10. The semiconductor layer 10 is, for example, a semiconductor substrate. The semiconductor layer 10 includes, for example, a silicon substrate. However, the embodiment is not limited thereto. The semiconductor layer 10 may include, for example, a semiconductor film provided on an insulating layer. Hereinbelow, an example is described in which a silicon substrate is used as the semiconductor layer 10.

The alignment mark unit 60 includes a mark unit semiconductor layer (not illustrated) and a mark unit insulating layer (not illustrated). In the example illustrated in FIG. 16, the alignment mark unit 60 is provided around the memory cell array unit 50 and the peripheral transistor PT. There are four alignment mark units 60 and one peripheral transistor PT. However, the disposition and the number of the alignment mark units 60 and the peripheral transistor PT are arbitrary. The planar configuration of the alignment mark unit 60 of the semiconductor memory device 130 may be similar to that of the semiconductor memory device 110, and a description is omitted. The cross-sectional configuration of the alignment mark unit 60 and the peripheral transistor PT of the semiconductor memory device 130 will now be described.

Herein, an axis perpendicular to the major surface 11 is taken as a Z-axis. One axis perpendicular to the Z-axis is taken as an X-axis. An axis perpendicular to the Z-axis and the X-axis is taken as a Y-axis.

FIG. 15A illustrates the configuration of the alignment mark unit 60 of the semiconductor memory device 130. Namely, FIG. 15A is a cross-sectional view along line C1-C2 of FIG. 4A.

FIGS. 15B and 15C illustrate the configuration of the peripheral transistor PT of the semiconductor memory device 130. Namely, FIG. 15B is a cross-sectional view along line D1-D2 of FIG. 16 and FIG. 15C is a cross-sectional view along line E1-E2 of FIG. 16.

As illustrated in FIG. 15A, the mark unit insulating layer 20a is filled into the mark unit semiconductor layer 10a.

The mark unit semiconductor layer 10a is a part of the semiconductor layer 10. The semiconductor layer 10 of the region of the alignment mark unit 60 is used to form the mark unit semiconductor layer 10a. The mark unit semiconductor layer 10a is, for example, a silicon substrate. In other words, the mark unit semiconductor layer 10a includes the same material as the material of the semiconductor layer 10.

The mark unit insulating layer 20a is juxtaposed with the mark unit semiconductor layer 10a. The mark unit insulating layer 20a includes the same material as the material of the device isolation insulating layer 20. For example, at least a part of the mark unit insulating layer 20a is formed simultaneously with the device isolation insulating layer 20 when forming the device isolation insulating layer 20.

For example, the semiconductor layer 10 is a silicon substrate; and the material of the device isolation insulating layer 20 may include at least one selected from silicon oxide and silicon nitride. A high-quality semiconductor memory device can be manufactured stably.

In the semiconductor memory device 130 according to the embodiment as illustrated in FIG. 15A, an upper surface 10u of the mark unit semiconductor layer 10a is included in a plane different from a plane including an upper surface 20u of the mark unit insulating layer 20a.

In the specific example, the upper surface 10u of the mark unit semiconductor layer 10a is disposed lower than the upper surface 20u of the mark unit insulating layer 20a. Thereby, the difference (e.g., the contrast) between the image of the mark unit semiconductor layer 10a and the image of the mark unit insulating layer 20a can be increased during the mask alignment.

Thereby, the alignment mark can be recognized easily; and the mask alignment precision can be increased. Also, misrecognition of the alignment mark can be suppressed; and productivity can be increased.

In such a case as well, it is desirable for the distance St from a plane (a plane perpendicular to the Z-axis) parallel to the major surface 11 and including the upper surface 10u of the mark unit semiconductor layer 10a to a plane (a plane perpendicular to the Z-axis) parallel to the major surface 11 and including the upper surface 20u of the mark unit insulating layer 20a to be not less than 40 nm.

The alignment mark unit 60 further includes a mark unit filled insulating layer 30a provided on the mark unit insulating layer 20a, where the mark unit filled insulating layer 30a includes the same material as the filled insulating film 30.

In the specific example, a mark unit tunneling insulating film TIa is provided on the mark unit semiconductor layer 10a. A mark unit charge retaining layer CLa is provided on the mark unit tunneling insulating film TIa. The mark unit tunneling insulating film TIa may include, for example, the material of the first tunneling insulating film TI1. The mark unit charge retaining layer CLa may include, for example, the material of the first charge retaining layer CL1.

In the specific example, a blocking insulating film (first blocking insulating film) BI1 is provided to cover the mark unit insulating layer 20a and the mark unit charge retaining layer CLa. A first liner film 22a is provided to cover the first blocking insulating film BI1. A second liner film 22b is provided to cover the first liner film 22a. The first liner film 22a may include, for example, a silicon oxide film by using TEOS. The second liner film 22b may include, for example, silicon nitride.

The upper surface of the second liner film 22b on the mark unit semiconductor layer 10a (on the mark unit charge retaining layer CLa) is positioned higher than the upper surface of the second liner film 22b on the mark unit insulating layer 20a. In other words, the mark unit filled insulating layer 30a is filled into the recess on the mark unit insulating layer 20a between the mark unit charge retaining layers Cla and provided to cover the second liner film 22b.

A first inter-layer insulating film 41 is provided on the mark unit filled insulating layer 30a. A second inter-layer insulating film 42 is provided on the first inter-layer insulating film 41. A cap insulating film 43 is provided on the second inter-layer insulating film 42. The first inter-layer insulating film 41 may include, for example, silicon oxide by using TEOS. The second inter-layer insulating film 42 may include, for example, silicon nitride. The cap insulating film 43 may include, for example, silicon oxide by using TEOS.

As illustrated in FIG. 15B and FIG. 15C, the peripheral transistor PT includes a charge retaining layer (a first charge retaining layer CL1).

In addition to the first charge retaining layer CL1, the peripheral transistor PT may further include, for example, a gate electrode (a gate-electrode first conductive layer GEf1 and a gate-electrode second conductive layer Gef2), a tunneling insulating film (a first tunneling insulating film TI1), a cap layer 73, and a blocking insulating film (a first blocking insulating film BI1). The gate-electrode first conductive film GEf1 and the gate-electrode second conductive film GEf2 oppose the semiconductor layer 10. The first charge retaining layer CL1 is provided between the semiconductor layer 10 and the gate-electrode first conductive layer GEf1. The first tunneling insulating film TI1 is provided between the semiconductor layer 10 and the first charge retaining layer CL1. The first blocking insulating film BI1 is provided between the first charge retaining layer CL1 and the gate-electrode first conductive layer GEf1. The cap layer 73 is provided on the gate-electrode second conductive layer GEf2.

The charge retaining layers (the first charge retaining layer CL1, etc.) are, for example, conductive. The charge retaining layers may include, for example, polysilicon. In other words, the semiconductor memory device 130 is, for example, a floating-gate nonvolatile semiconductor memory device.

The gate electrodes (the gate-electrode first conductive layer GEf1 and gate-electrode second conductive layer Gef2, etc.) are, for example, conductive. The gate-electrode first conductive layer GEf1 may include, for example, polysilicon. The gate-electrode second conductive layer Gef2 may include, for example, polysilicon and/or a metal silicide. The tunneling insulating films (e.g., the first tunneling insulating film TI1, etc.) are, for example, insulative. The tunneling insulating films may include, for example, silicon oxide. The blocking insulating films (e.g., the first blocking insulating film BI1, etc.) are, for example, insulative. The blocking insulating films may include, for example, silicon oxide. An opening is provided in the first blocking insulating film BI1 of the peripheral transistor PT; and the gate-electrode second conductive layer GEf2 is connected to the first charge retaining layer CL1.

As illustrated in FIG. 15B and FIG. 15C, the gate-electrode second conductive film GEf2 has a portion opposing at least a part of a side surface (a surface along the Z-axis) of the first charge retaining layer CL1.

The first blocking insulating film BI1 is, for example, IPD (Inter-poly Dielectric) film.

The cap layer 73 may include, for example, silicon nitride.

The device isolation insulating layer 20 partitions the peripheral transistor PT from other elements not illustrated.

In the specific example, the first blocking insulating film BI1 is provided to cover the mark unit insulating layer 20a and the mark unit charge retaining layer CLa. The first liner film 22a is provided to cover the device isolation insulating layer 20, the first charge retaining layer CL1, the first tunneling insulating film TI1, the gate electrode (the gate-electrode first conductive layer GEf1 and the gate-electrode second conductive layer GEf2), and the cap layer 73. The second liner film 22b is provided to cover the first liner film 22a. The filled insulating film 30 is filled into the recess on the second liner film 22b.

The first inter-layer insulating film 41 is provided on the filled insulating film 30 and the cap layer 73. The second inter-layer insulating film 42 is provided on the first inter-layer insulating film 41. The cap insulating film 43 is provided on the second inter-layer insulating film 42.

One example of a method for manufacturing the semiconductor memory device 130 will now be described.

The Flowchart shown in FIG. 5 illustrates one example of the method for manufacturing the semiconductor memory device 130.

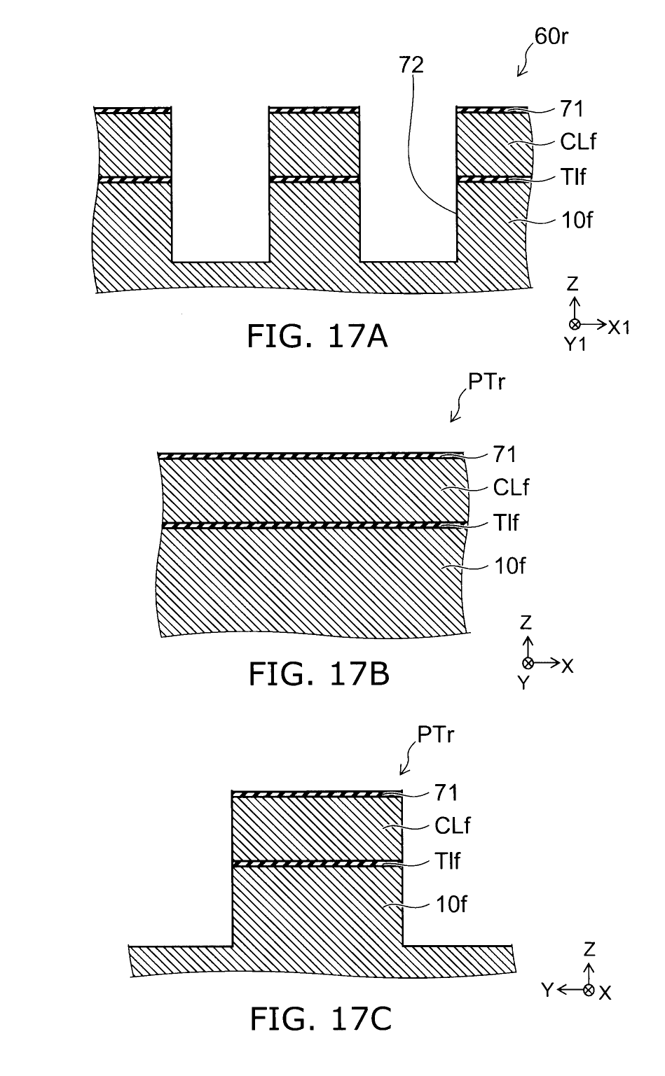

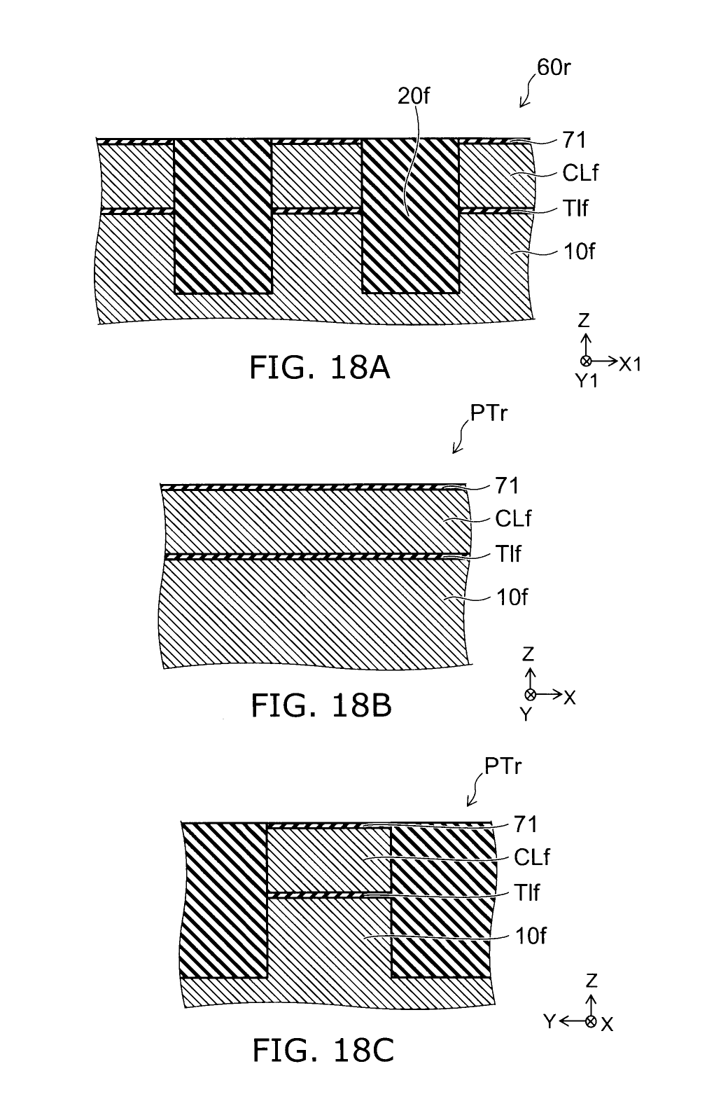

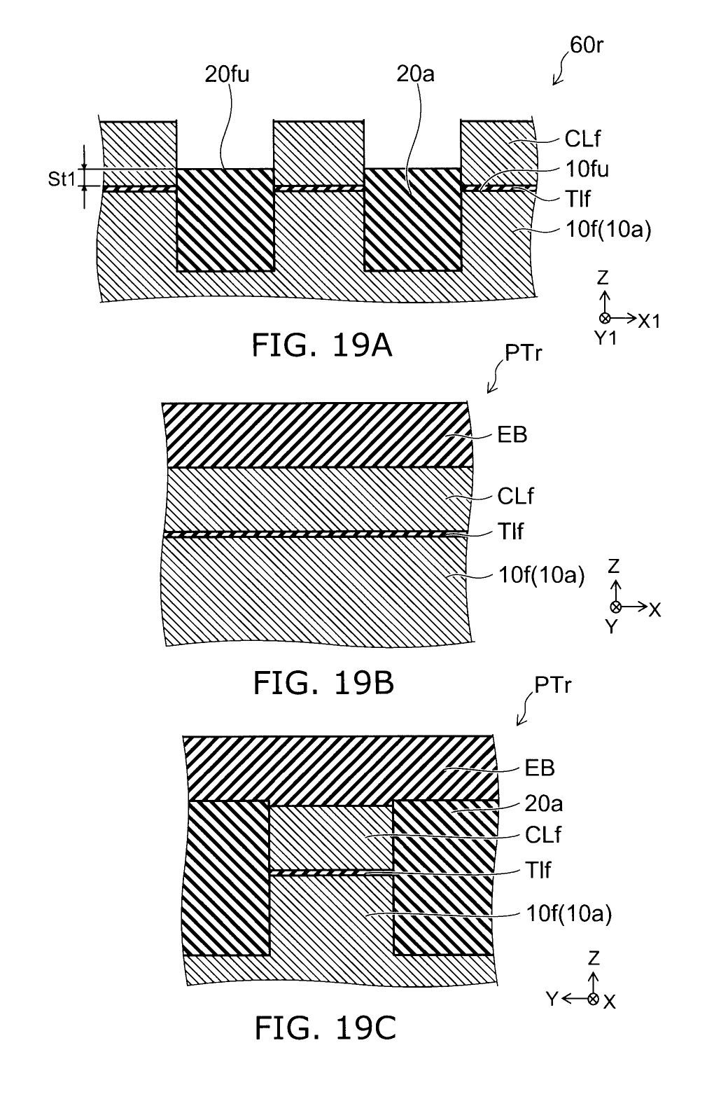

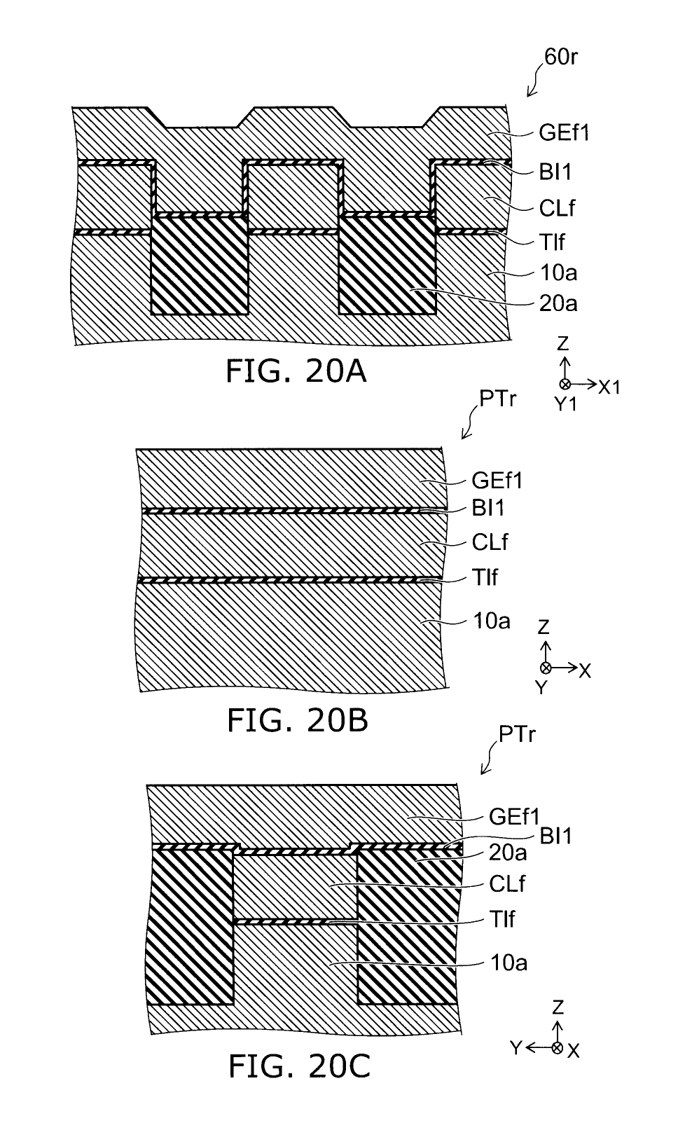

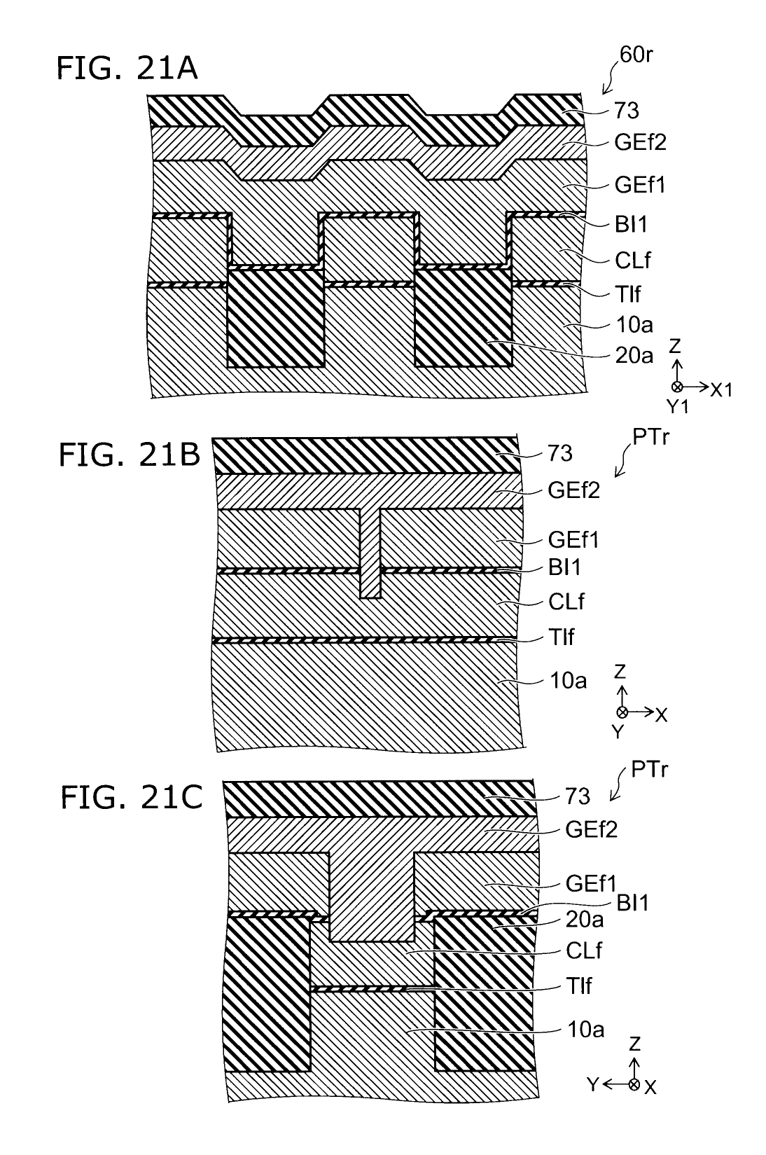

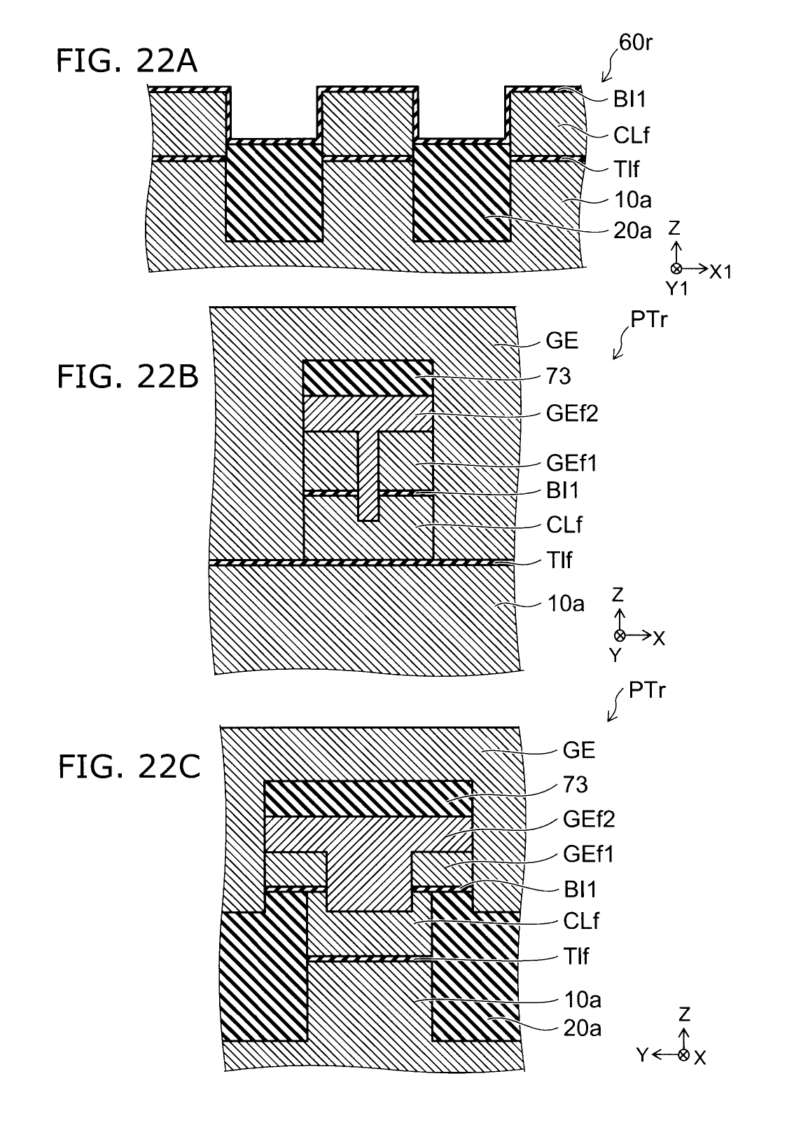

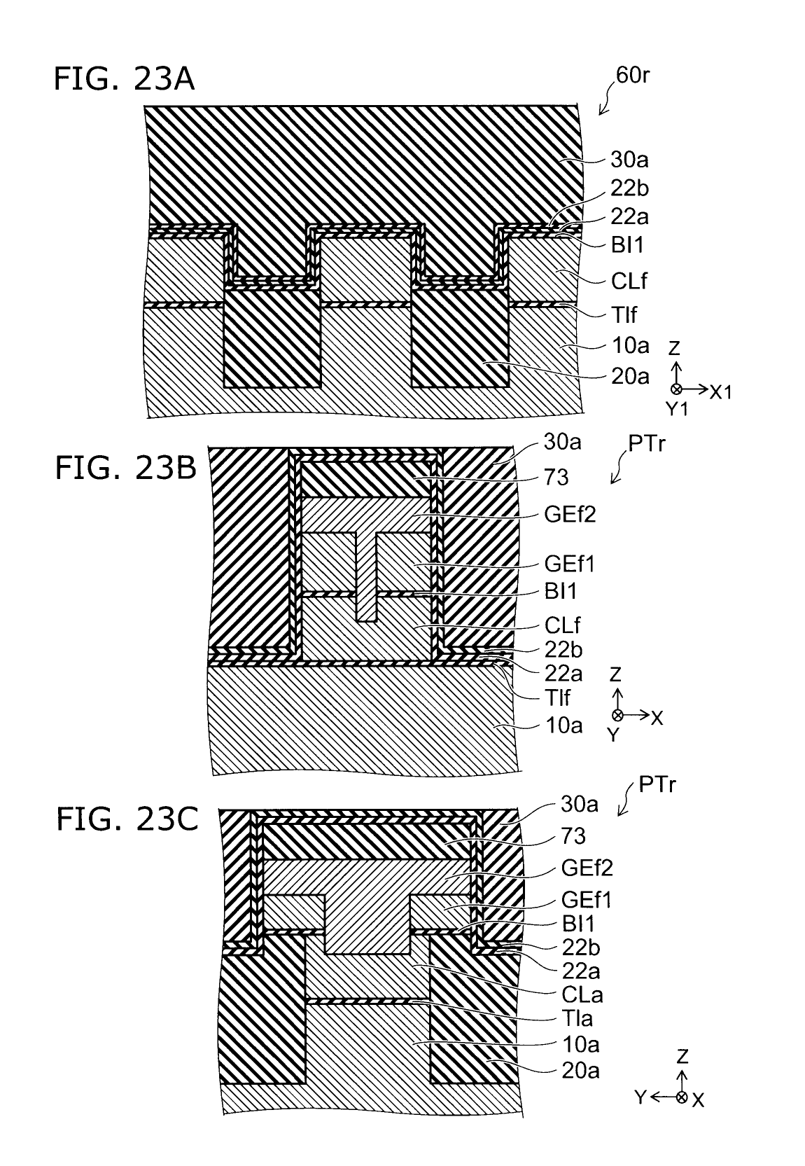

FIG. 17A to FIG. 17C, FIG. 18A to FIG. 18C, FIG. 19A to FIG. 19C, FIG. 20A to FIG. 20C, FIG. 21A to FIG. 21C, FIG. 22A to FIG. 22C, and FIG. 23A to FIG. 23C are schematic cross-sectional views in order of the processes, illustrating the method for manufacturing the semiconductor memory device according to the third embodiment.

FIG. 17A to FIG. 23A are cross-sectional views related to the alignment mark unit 60. FIG. 17B to FIG. 23B and FIG. 17C to FIG. 23C are cross-sectional views related to the peripheral transistor PT.

In the manufacturing method as illustrated in FIG. 5 and FIG. 6A, a charge retaining film CLf is formed in a base body upper surface 10fu of a mark unit region 60r and a peripheral transistor region PTr of a base body 10f (step S110). The base body 10f is used to form the semiconductor layer 10 and the mark unit semiconductor layer 10a. The mark unit region 60r is the region where the alignment mark unit 60 of the base body 10f is formed. The peripheral transistor region PTr is used to form the peripheral transistor PT. The charge retaining film CLf is a film used to form the charge retaining layers (the first charge retaining layers CL1) included in the peripheral transistor PT and included in the memory cells MC (the first memory cells) included in the first memory string MS1 and the charge retaining layers (the second charge retaining layers CL2) included in the memory cells MC (the second memory cells MC2) included in the second memory string MS2.

Specifically, a tunneling-film insulating film TIf is formed on the base body upper surface 10fu. The tunneling-film insulating film TIf is a film used to form the tunneling insulating films (e.g., the first tunneling insulating film TI1, the second tunneling insulating film TI2, etc.). Then, the charge retaining film CLf is formed on the tunneling-film insulating film TIf.

Then, a silicon nitride film 71 is formed on the charge retaining film CLf for protection.

As illustrated in FIG. 5 and FIG. 17A to FIG. 17C, a mark unit trench 72 into which the mark unit insulating layer 20a is filled is made in the charge retaining film CLf and the base body 10f (step S120).

Simultaneously with the making of the mark unit trench 72, for example, a trench 72a into which the device isolation insulating layer 20 is filled is made in the memory cell array unit 50 and in a proximity of the peripheral transistor region PTr.

As illustrated in FIG. 5 and FIG. 18A to FIG. 18C, an insulating layer 20f is filled into the mark unit trench 72 and the trench 72a (step S130). The insulating layer 20f is used to form at least a part of the mark unit insulating layer 20a and the device isolation insulating layer 20.

As illustrated in FIG. 5 and FIG. 19A to FIG. 19C, an upper surface 20fu of the insulating layer 20f is caused to be positioned lower than the charge retaining film CLf and higher than the base body upper surface 10fu by etching the insulating layer 20f filled into the mark unit trench 72. At this time, the peripheral transistor region PTr is covered by a resist mask EB (step S140).

In other words, the upper surface 20fu of the insulating layer 20f is higher than the base body upper surface 10fu. The insulating layer 20f after the etching is used to form the mark unit insulating layer 20a. The base body 10f is used to form the mark unit semiconductor layer 10a. The base body upper surface 10fu is used to form the upper surface 10u of the mark unit semiconductor layer 10a.

Thus, the manufacturing method includes a process of forming a difference in levels by causing the upper surface 20fu of the insulating layer 20f filled into the mark unit trench 72 to be included in a plane different from a plane including the base body upper surface 10fu of the base body 10f of the mark unit region 60r by etching at least one selected from the insulating layer 20f filled into the mark unit trench 72 and the base body upper surface 10fu of the base body 10f of the mark unit region 60r.

Thereby, the semiconductor memory device 130 is manufactured with a configuration in which the upper surface 10u of the mark unit semiconductor layer 10a is included in a plane different from a plane including the upper surface 20u of the mark unit insulating layer 20a.

A distance St1 along the Z-axis from the upper surface 20fu of the insulating layer 20f to the base body upper surface 10fu corresponds to the difference in levels (the distance St along the Z-axis) from the upper surface 10u of the mark unit semiconductor layer 10a to the upper surface 20u of the mark unit insulating layer 20a. It is desirable for the distance St1 along the Z-axis from the upper surface 20fu of the insulating layer 20f to the base body upper surface 10fu to be not less than 40 nm.

As illustrated in FIG. 5, the manufacturing method may further include patterning the gate electrodes (the gate-electrode first conductive layer GEf1 and the gate-electrode second conductive layer GEf2) included in the peripheral transistor PT (step S150).

For example, as illustrated in FIG. 20A to FIG. 20C, a first blocking insulating film BI1 is formed on the mark unit insulating layer 20a and on the charge retaining film CLf. The gate-electrode first conductive layer GEf1 is formed on the first blocking insulating film BI1. Although not illustrated, the gate-electrode first conductive layer GEf1 is formed also in the memory cell array unit 50.

As illustrated in FIG. 21A to FIG. 21C, a gate-electrode second conductive layer GEf2 is formed on the gate-electrode first conductive layer GEf1. A cap layer 73 is formed on the gate-electrode second conductive layer GEf2. Although not illustrated, the gate-electrode second conductive layer GEf2 and the cap layer 73 are formed also in the memory cell array unit 50.

The gate-electrode first conductive layer GEf1 may include, for example, polysilicon. The gate-electrode second conductive layer GEf2 may include, for example, polysilicon and/or a metal silicide. The cap layer 73 may include, for example, silicon nitride.

Then, although not illustrated, the gate electrodes (e.g., the first gate electrode GE1, the second gate electrode GE2, etc.) of the memory cell array unit 50 and the peripheral transistor PT are patterned. In other words, step S150 is implemented.

Thereby, as illustrated in FIG. 22A to FIG. 22C, the gate-electrode first conductive layer GEf1, the gate-electrode second conductive layer GEf2, and the cap layer 73 are removed in the alignment mark unit 60 (the mark unit region 60r). The charge retaining film CLf, the first blocking insulating film BI1, the gate-electrode first conductive layer GEf1, the gate-electrode second conductive layer GEf2, and the cap layer 73 are patterned in the peripheral transistor PT.

Then, as illustrated in FIG. 5, the manufacturing method may further include forming the mark unit filled insulating layer 30a on the blocking insulating film BI1 and the insulating layer 20f (the mark unit insulating layer 20a) which is recessed lower than the charge retaining film CLf by performing etching after the filling into the mark unit trench 72 (step S160).

For example, as illustrated in FIG. 23A to FIG. 23C, the first liner film 22a is formed to cover the first blocking insulating film BI1 on the insulating layer 20f (the mark unit insulating layer 20a) and the charge retaining film CLf. The second liner film 22b is formed on the first liner film 22a. The mark unit filled insulating layer 30a is formed on the second liner film 22b. The mark unit filled insulating layer 30a is filled into the recess between the charge retaining films CLf (on the mark unit insulating layer 20a). Then, the upper surface is planarized if necessary.

Although not illustrated, the formation of the mark unit filled insulating layer 30a is performed simultaneously with, for example, the formation of the filled insulating film 30 of the memory cell array unit 50.

The first inter-layer insulating film 41 is formed on the mark unit filled insulating layer 30a and the second liner film 22b. Then, the second inter-layer insulating film 42 is formed on the first inter-layer insulating film 41. Then, the cap insulating film 43 is formed on the second inter-layer insulating film 42.

Thereby, the alignment mark unit 60 illustrated in FIG. 1 is formed. According to the manufacturing method, the semiconductor memory device 110 in which the upper surface 10u of the mark unit semiconductor layer 10a is disposed lower than the upper surface 20u of the mark unit insulating layer 20a can be manufactured with high productivity. According to the manufacturing method, the alignment mark can be recognized easily; and the mask alignment precision can be increased. Misrecognition of the alignment mark can be suppressed; and productivity can be increased.

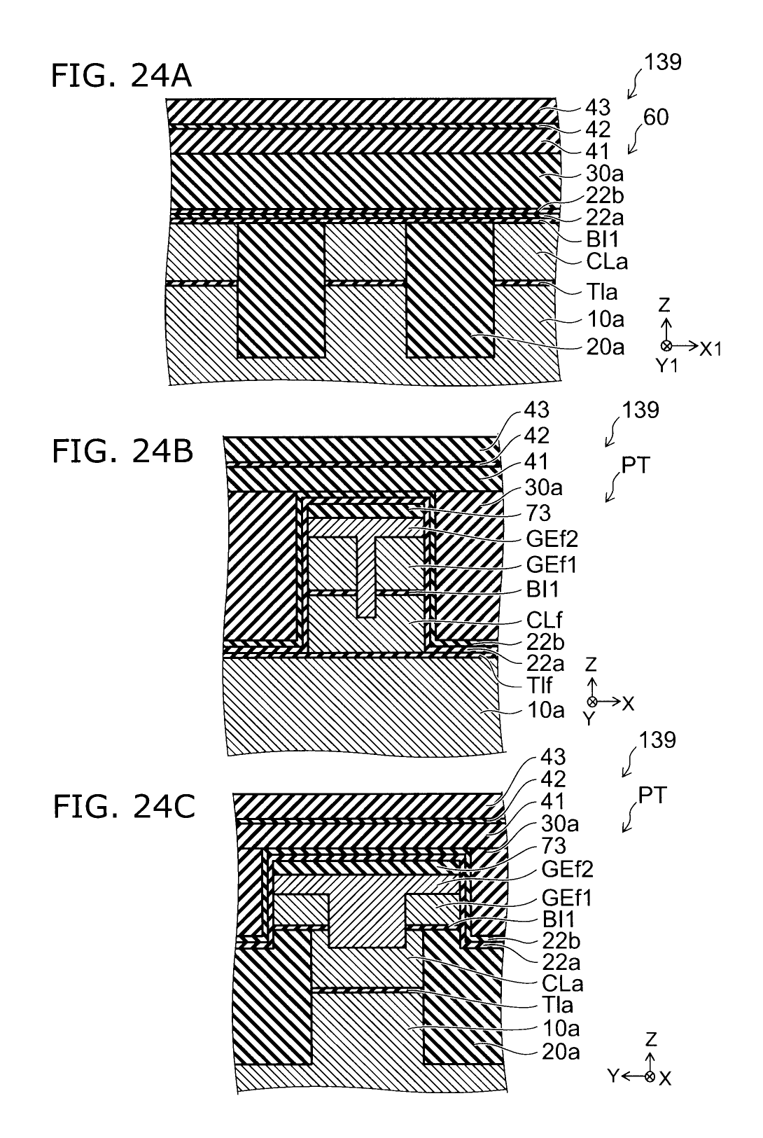

FIG. 24A to FIG. 24C are schematic cross-sectional views illustrating the configuration of a part of a semiconductor memory device of a second reference example.

Namely, FIG. 24A illustrates the configuration of the alignment mark unit 60 of the semiconductor memory device 139 of the second reference example. FIG. 24B and FIG. 24C illustrate the configuration of the peripheral transistor PT of the semiconductor memory device 139 of the second reference example.

In the second reference example as illustrated in FIG. 24A to FIG. 24C, the upper surface 10u of the mark unit semiconductor layer 10a is included in the same plane as a plane including the upper surface 20u of the mark unit insulating layer 20a. In other words, the upper surface 20u and the upper surface 10u are disposed in substantially the same plane. Therefore, the difference (e.g., the contrast) between the image of the mark unit semiconductor layer 10a and the image of the mark unit insulating layer 20a is small. Therefore, the alignment mark is difficult to recognize. Therefore, it is difficult to improve the mask alignment precision. Also, misrecognition of the alignment mark occurs easily; and productivity is low.

The peripheral transistor PT has a configuration in which a difference in levels is provided from the upper surface of the semiconductor layer 10 to the upper surface of the device isolation insulating layer 20.

For example, in the peripheral transistor PT of the semiconductor memory device 130 according to the embodiment as illustrated in FIG. 15B and FIG. 15C as well, the upper surface of the device isolation insulating layer 20 is disposed higher than the upper surface of the semiconductor layer 10.

For example, in the semiconductor memory device 139 of the second reference example illustrated in FIG. 24A to FIG. 24C as well, although the upper surface of the device isolation insulating layer 20 is disposed higher than the upper surface of the semiconductor layer 10, the upper surface 10u of the mark unit semiconductor layer 10a is included in the plane including the upper surface 20u of the mark unit insulating layer 20a. Therefore, as recited above, the alignment mark is difficult to recognize.

In the embodiment, the alignment mark is easy to recognize because the upper surface 10u of the mark unit semiconductor layer 10a is disposed inside a plane different from the plane including the upper surface 20u of the mark unit insulating layer 20a.

### Fourth Embodiment

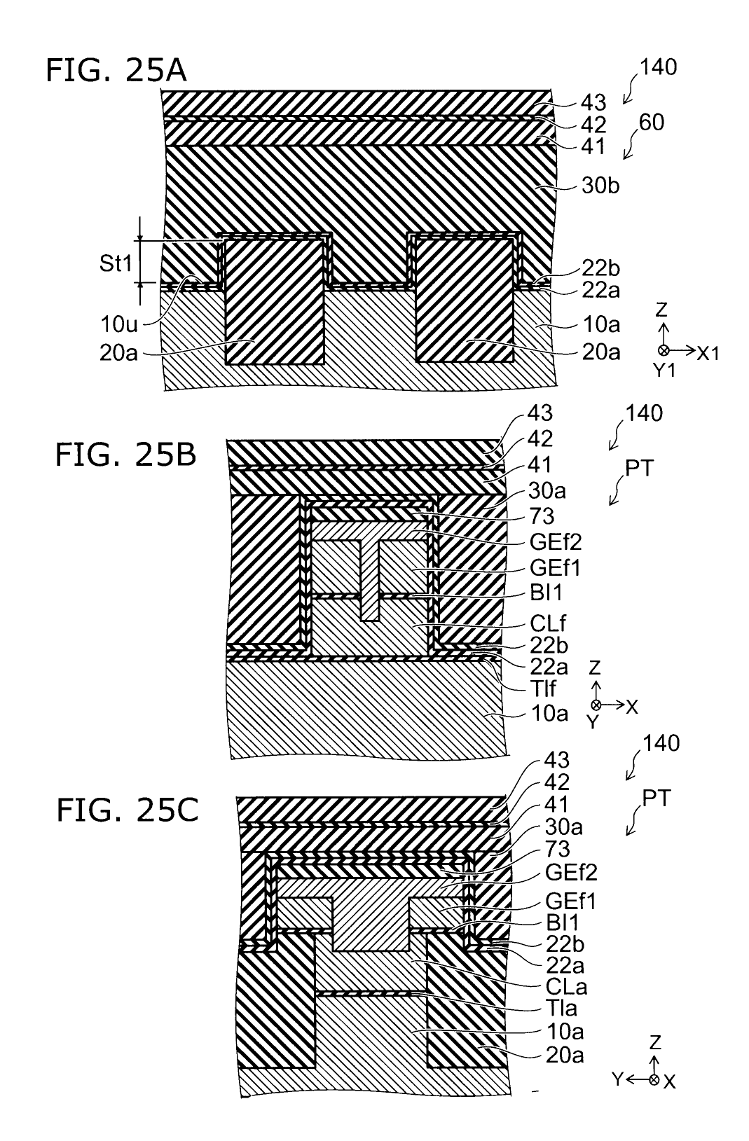

FIG. 25A to FIG. 25C are schematic cross-sectional views illustrating the configuration of a part of a semiconductor memory device according to a fourth embodiment.

Namely, FIG. 25A illustrates an example of the configuration of the alignment mark unit 60 of the semiconductor memory device 140 according to the embodiment. FIG. 25B and FIG. 25C illustrate the example of the configuration of the peripheral transistor PT of the semiconductor memory device 140 according to the embodiment.

The configuration of the peripheral transistor PT of the semiconductor memory device 140 may be similar to that of the semiconductor memory device 130, and a description is omitted.

The configuration of the memory cell array unit 50 of the semiconductor memory device 140 may be similar to that of the semiconductor memory device 110, and a description is omitted. The planar configuration of the alignment mark unit 60 of the semiconductor memory device 140 may be similar to that of the semiconductor memory device 110, and a description is omitted. The cross-sectional configuration of the alignment mark unit 60 of the semiconductor memory device 140 will now be described.

FIG. 25A is a cross-sectional view corresponding to a cross section along line C1-C2 of FIG. 4A. FIG. 25B is a cross-sectional view corresponding to a cross section along line D1-D2 of FIG. 16. FIG. 25C is a cross-sectional view corresponding to a cross section along line E1-E2 of FIG. 16.

In the semiconductor memory device 140 as illustrated in FIG. 25A as well, the mark unit insulating layer 20a is filled into the mark unit semiconductor layer 10a.

The mark unit semiconductor layer 10a is a part of the semiconductor layer 10.

The mark unit insulating layer 20a is juxtaposed with the mark unit semiconductor layer 10a. The mark unit insulating layer 20a includes the same material as the material of the device isolation insulating layer 20.

In the semiconductor memory device 140 as illustrated in FIG. 25A as well, the upper surface 10u of the mark unit semiconductor layer 10a is included in a plane different from the plane including the upper surface 20u of the mark unit insulating layer 20a.

In the specific example, the upper surface 10u of the mark unit semiconductor layer 10a is disposed lower than the upper surface 20u of the mark unit insulating layer 20a. Thereby, the difference (e.g., the contrast) between the image of the mark unit semiconductor layer 10a and the image of the mark unit insulating layer 20a can be increased during the mask alignment.

Thereby, the alignment mark can be recognized easily; and the mask alignment precision can be increased. Also, misrecognition of the alignment mark can be suppressed; and productivity can be increased.

In such a case as well, it is desirable for the distance St from a plane (a plane perpendicular to the Z-axis) parallel to the major surface 11 and including the upper surface 10u of the mark unit semiconductor layer 10a to a plane (a plane perpendicular to the Z-axis) parallel to the major surface 11 and including the upper surface 20u of the mark unit insulating layer 20a to be not less than 40 nm.

In the semiconductor memory device 140, the difference in levels (the distance St) from the upper surface 10u of the mark unit semiconductor layer 10a to the upper surface 20u of the mark unit insulating layer 20a in the alignment mark unit 60 is larger than the difference in levels from the upper surface of the semiconductor layer 10 to the upper surface of the device isolation insulating layer 20 in the memory cell MC of the memory cell array unit 50.

In the semiconductor memory device 140, the alignment mark unit 60 further includes a mark unit filled insulating layer 30b provided on the mark unit semiconductor layer 10a, where the mark unit filled insulating layer 30b includes the same material as that of the filled insulating film 30.

In the specific example, the first liner film 22a is provided to cover the mark unit insulating layer 20a and the mark unit semiconductor layer 10a. The second liner film 22b is provided to cover the first liner film 22a. The first liner film 22a may include, for example, a silicon oxide film by using TEOS. The second liner film 22b may include, for example, silicon nitride.

The upper surface of the second liner film 22b on the mark unit insulating layer 20a is positioned higher than the upper surface of the second liner film 22b on the mark unit semiconductor layer 10a. In other words, the mark unit filled insulating layer 30b is filled into the recess on the mark unit semiconductor layer 10a between the mark unit insulating layers 20a. The mark unit filled insulating layer 30b is provided to cover the second liner film 22b.

The first inter-layer insulating film 41 is provided on the mark unit filled insulating layer 30b. The second inter-layer insulating film 42 is provided on the first inter-layer insulating film 41. The cap insulating film 43 is provided on the second inter-layer insulating film 42.

One example of a method for manufacturing the semiconductor memory device 140 will now be described.

The Flowchart shown in FIG. 11 illustrates one example of the method for manufacturing the semiconductor memory device 140.

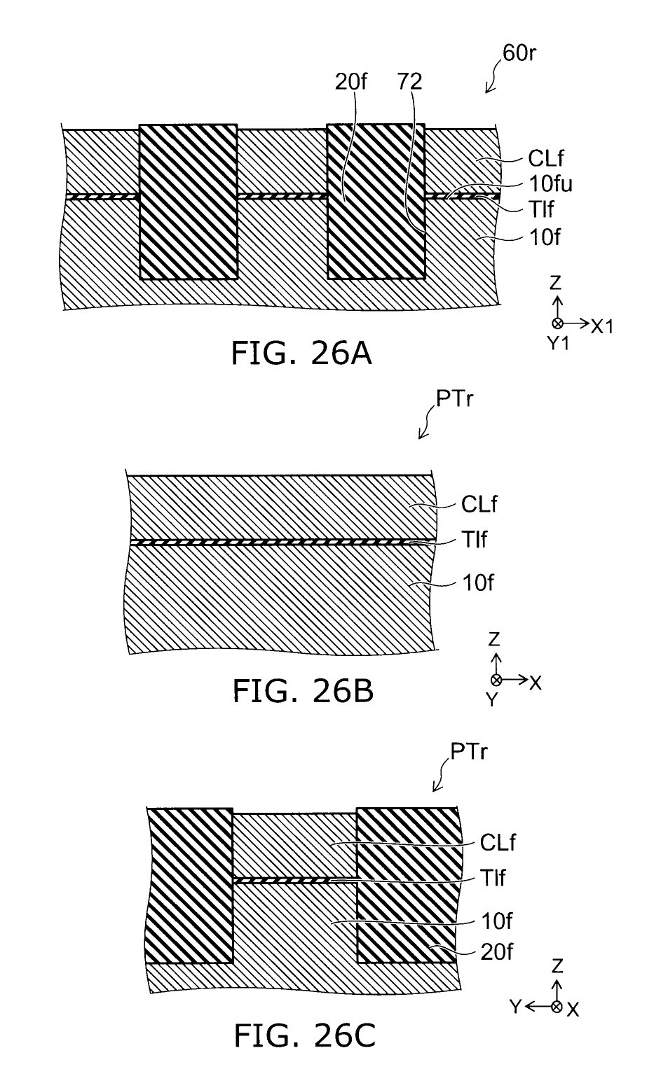

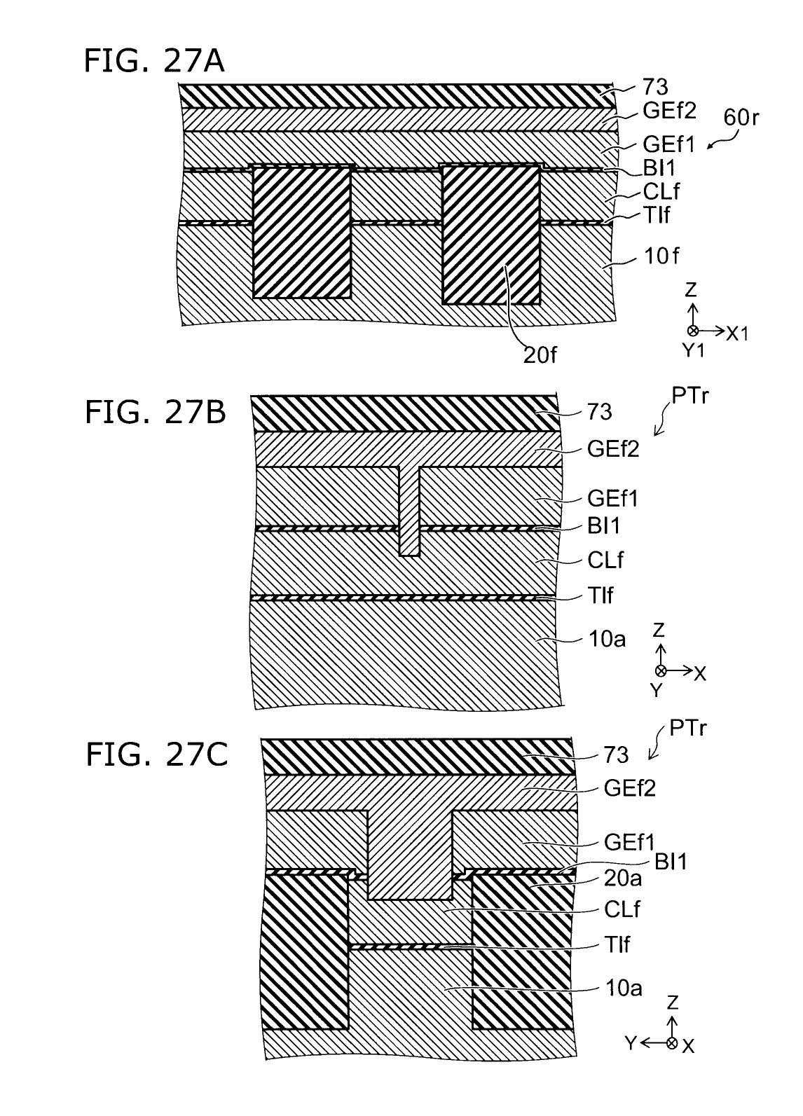

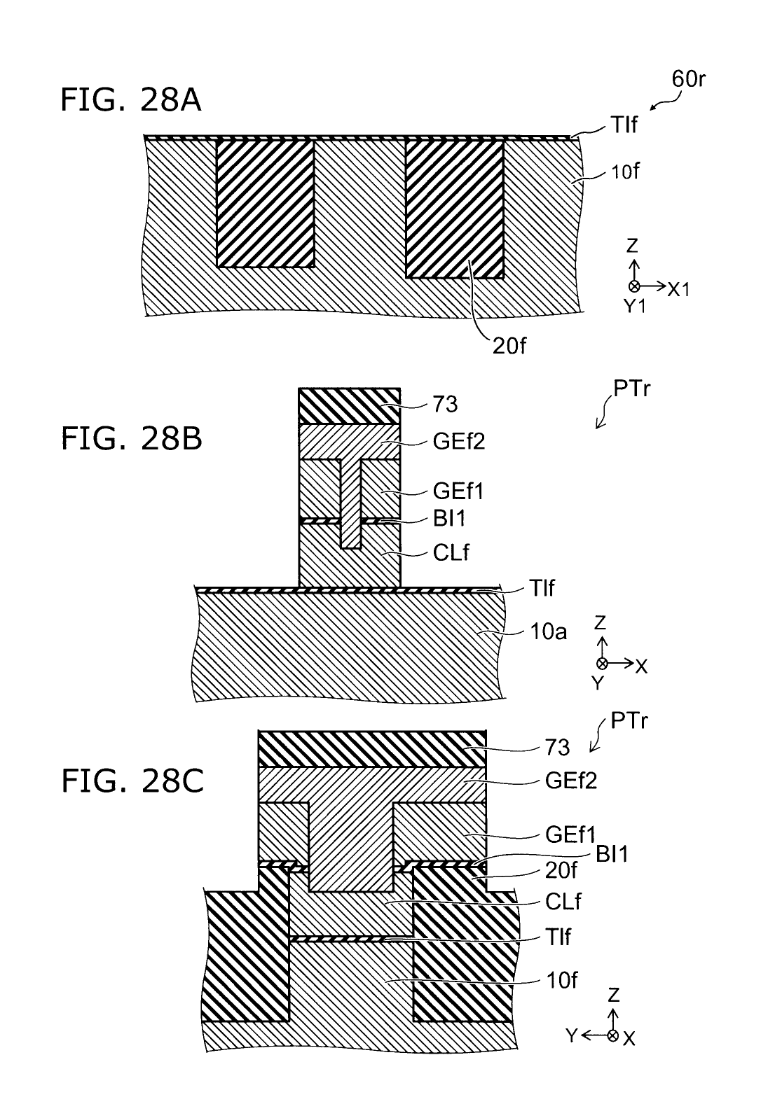

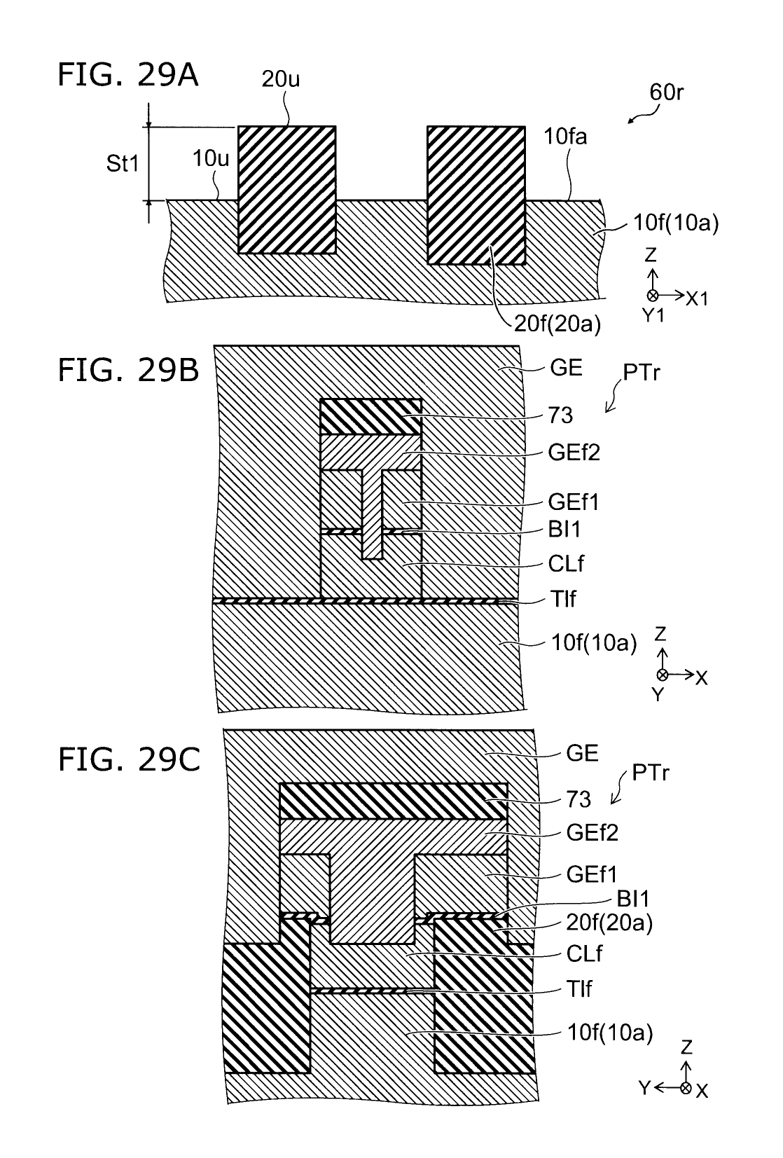

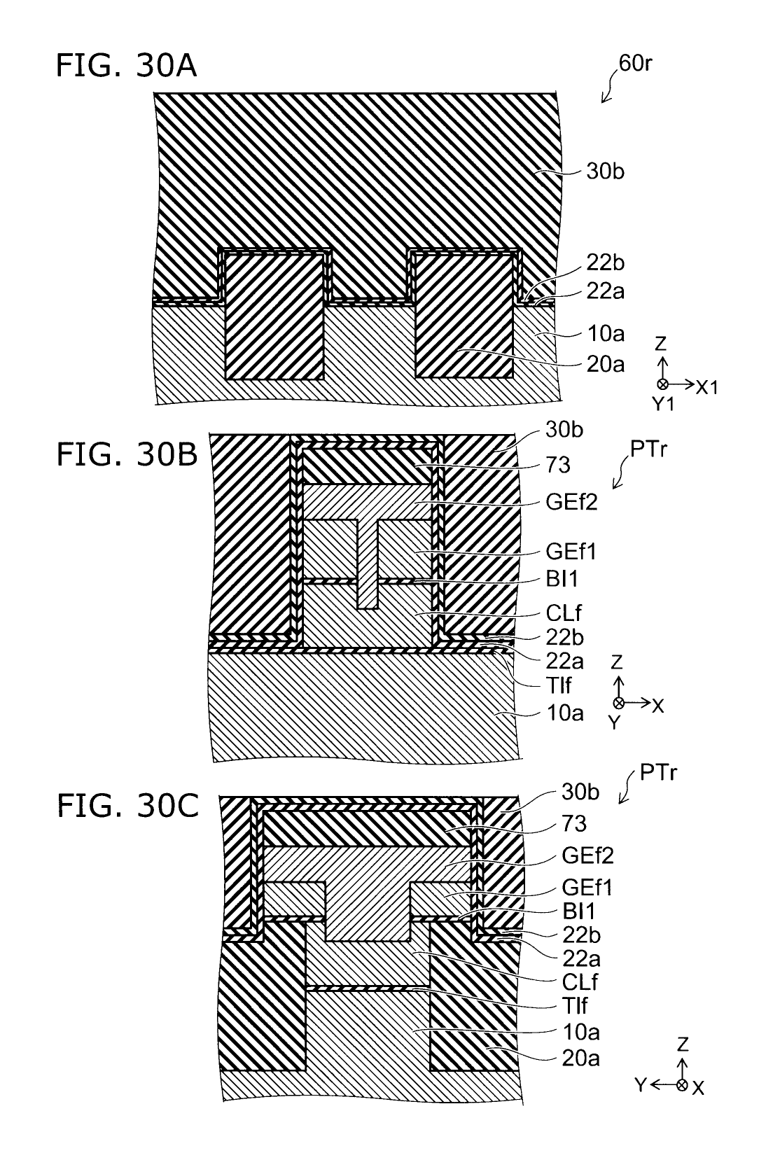

FIG. 26A to FIG. 26C, FIG. 27A to FIG. 27C, and FIG. 28A to FIG. 28C, FIG. 29A to FIG. 29C, and FIG. 30A to FIG. 30C are schematic cross-sectional views in order of the processes, illustrating the method for manufacturing the semiconductor memory device according to the fourth embodiment.

FIG. 26A to FIG. 30A are cross-sectional views related to the alignment mark unit 60. FIG. 26B to FIG. 30B and FIG. 26C to FIG. 30C are cross-sectional views related to the peripheral transistor PT.

As illustrated in FIG. 11 and FIG. 26A to FIG. 26C, the charge retaining film CLf used to form the charge retaining layers (the first charge retaining layers CL1) included in the memory cells MC (the first memory cells MC1) included in the first memory string MS1 and the charge retaining layers (the second charge retaining layers CL2) included in the memory cells MC (the second memory cells MC2) included in the second memory string MS2 is formed on the base body upper surface 10fu of the mark unit region 60r and the peripheral transistor region PTr of the base body 10f used to form the semiconductor layer 10 and the mark unit semiconductor layer 10a where the alignment mark unit 60 is formed (step S210).

Specifically, the tunneling-film insulating film TIf used to form the tunneling insulating films (e.g., the first tunneling insulating film TI1, the second tunneling insulating film TI2, etc.) is formed on the base body upper surface 10fu. Then, the charge retaining film CLf is formed on the tunneling-film insulating film TIf.

Continuing as illustrated in FIG. 11 and FIG. 26A, the mark unit trench 72 into which the mark unit insulating layer 20a is filled is made in the charge retaining film CLf and the base body 10f (step S220).

Simultaneously with the making of the mark unit trench 72, for example, a trench 72a into which the device isolation insulating layer 20 is filled is made in the memory cell array unit 50 and in a proximity of the peripheral transistor region PTr.

Then, as illustrated in FIG. 11 and FIG. 26A to FIG. 26C, the insulating layer 20f is filled into the mark unit trench 72 (step S230). The insulating layer 20f is used to form at least a part of the mark unit insulating layer 20a and the device isolation insulating layer 20.

As illustrated in FIG. 11, the gate electrodes (the first gate electrodes GE1) included in the memory cells MC (the first memory cells MC1) included in the first memory string MS1 and the gate electrodes (the second gate electrodes GE2) included in the memory cells MC (the second memory cells MC2) included in the second memory string MS2 are patterned (step S240); and the charge retaining film CLf formed in the mark unit region 60r is removed (step S250). For example, step S250 can be implemented simultaneously with step S240.

Specifically, as illustrated in FIG. 27A to FIG. 27C, the first blocking insulating film BI1 is formed on the insulating layer 20f filled into the mark unit trench 72 and on the charge retaining film CLf. The gate-electrode first conductive layer GEf1 is formed on the first blocking insulating film BI1. Although not illustrated, the gate-electrode first conductive layer GEf1 is formed also in the memory cell array unit 50.

Then, the gate-electrode second conductive layer GEf2 is formed on the gate-electrode first conductive layer GEf1. The cap layer 73 is formed on the gate-electrode second conductive layer GEf2. Although not illustrated, the gate-electrode second conductive layer GEf2 and the cap layer 73 are formed also in the memory cell array unit 50.

The gate-electrode first conductive layer GEf1 may include, for example, polysilicon. The gate-electrode second conductive layer GEf2 may include, for example, polysilicon and/or a metal silicide. The cap layer 73 may include, for example, silicon nitride.

Then, although not illustrated, the gate electrodes (e.g., the first gate electrode GE1, the second gate electrode GE2, etc.) of the memory cell array unit 50 are patterned. In other words, step S240 is implemented.

At this time, as illustrated in FIG. 28A, the first blocking insulating film BI1, the charge retaining film CLf, the gate-electrode first conductive layer GEf1, the gate-electrode second conductive layer GEf2, and the cap layer 73 of the alignment mark unit 60 (the mark unit region 60r) are removed (step S250). The charge retaining film CLf, the first blocking insulating film BI1, gate-electrode first conductive layer GEf1, the gate-electrode second conductive layer GEf2, and the cap layer 73 are patterned in the peripheral transistor PT. In other words, step S250 is implemented.

As illustrated in FIG. 11 and FIG. 29A, the base body upper surface 10fu of the base body 10f of the mark unit region 60r exposed by the removal of the charge retaining film CLf is etched (step S260); and the base body upper surface 10fu is caused to be lower than the insulating layer 20f filled into the mark unit trench 72. At this time, the peripheral transistor PT is covered by a resist mask EB.

The base body 10f in which the base body upper surface 10fu is etched is used to form the mark unit semiconductor layer 10a. The insulating layer 20f filled into the mark unit trench 72 is used to form the mark unit insulating layer 20a.

Thereby, the upper surface 10u of the mark unit semiconductor layer 10a is positioned lower than the upper surface 20u of the mark unit insulating layer 20a.

As illustrated in FIG. 11, the manufacturing method may further include forming the mark unit filled insulating layer 30b on the etched base body 10f (the mark unit semiconductor layer 10a).

Specifically, as illustrated in FIG. 30A to FIG. 30C, the first liner film 22a is formed to cover the mark unit semiconductor layer 10a and the mark unit insulating layer 20a. Then, the second liner film 22b is formed on the first liner film 22a. Then, the mark unit filled insulating layer 30b is formed on the second liner film 22b. The mark unit filled insulating layer 30b is filled into the recess between the mark unit insulating layers 20a (on the mark unit semiconductor layer 10a). Then, the upper surface is planarized if necessary.

Continuing, the first inter-layer insulating film 41 is formed on the mark unit filled insulating layer 30b and the second liner film 22b. Then, the second inter-layer insulating film 42 is formed on the first inter-layer insulating film 41. The cap insulating film 43 is formed on the second inter-layer insulating film 42.

Thereby, the alignment mark unit 60 and the peripheral transistor PT illustrated in FIG. 25A to FIG. 25C are formed. According to the manufacturing method, the semiconductor memory device 140 in which the upper surface 10u of the mark unit semiconductor layer 10a is disposed lower than the upper surface 20u of the mark unit insulating layer 20a can be manufactured with high productivity. According to the manufacturing method, the alignment mark can be recognized easily; and the mask alignment precision can be increased. Further, misrecognition of the alignment mark can be suppressed; and productivity can be increased.

FIG. 14 is a schematic cross-sectional view illustrating another method for manufacturing the semiconductor memory device according to the embodiment.

FIG. 14 illustrates the process after the process illustrated in FIG. 12B.

In this manufacturing method as illustrated in FIG. 14, the gate-electrode first conductive layer GEf1, the gate-electrode second conductive layer GEf2, and the cap layer 73 are formed sequentially on the insulating layer 20f filled into the mark unit trench 72 and on the charge retaining film CLf; and the insulating layer 20f is exposed by etching the gate-electrode first conductive layer GEf1, the gate-electrode second conductive layer GEf2, and the cap layer 73. Then, the upper surface (the upper surface 20u) of the insulating layer 20f is positioned lower than the charge retaining film CLf and higher than the base body upper surface 10fu (the upper surface 10u).

By this method as well, the upper surface 10u of the mark unit semiconductor layer 10a is positioned lower than the upper surface 20u of the mark unit insulating layer 20a.

However, in this method, there are cases where, for example, a part (a polysilicon film) of at least one selected from the gate-electrode first conductive layer GEf1 and the gate-electrode second conductive layer GEf2 remains on the insulating layer 20f in the etching recited above. Therefore, as described in regard to FIG. 12B to FIG. 13A, it is more desirable for the base body upper surface 10fu of the base body 10f of the mark unit region 60r to be etched (step S260) after the tunneling-film insulating film TIf, the charge retaining film CLf, the gate-electrode first conductive layer GEf1, the gate-electrode second conductive layer GEf2, and the cap layer 73 of the alignment mark unit 60 (the mark unit region 60r) are removed (step S250).

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor memory devices such as semiconductor layers, memory strings, memory cells, device isolation insulating layers, alignment mark units, mark unit semiconductor layers, mark unit insulating layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor memory devices, semiconductor wafers, and methods for manufacturing semiconductor memory devices practicable by an appropriate design modification by one skilled in the art based on the semiconductor memory devices, the semiconductor wafers, and the methods for manufacturing semiconductor memory devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device, comprising:
a memory cell array unit including
a first memory string provided on a major surface of a semiconductor layer,
a second memory string juxtaposed with the first memory string on the major surface, and
a device isolation insulating layer partitioning the first memory string and the second memory string from each other; and
an alignment mark unit juxtaposed with the memory cell array unit, the alignment mark unit including
a mark unit semiconductor layer, the mark unit semiconductor layer being a part of the semiconductor layer, and
a mark unit insulating layer juxtaposed with the mark unit semiconductor layer, the mark unit insulating layer including a material same as a material of the device isolation insulating layer,
an upper surface of the mark unit semiconductor layer being included in a plane different from a plane including an upper surface of the mark unit insulating layer when a direction of the major surface side defines the direction of an upper direction.

2. The device according to claim 1, wherein a distance from a plane parallel to the major surface and including the upper surface of the mark unit semiconductor layer to a plane parallel to the major surface and including the upper surface of the mark unit insulating layer being not less than 40 nanometers.

3. The device according to claim 1, wherein the upper surface of the mark unit semiconductor layer is positioned lower than the upper surface of the mark unit insulating layer.

4. The device according to claim 1, wherein:
the first memory string, the second memory string, and the device isolation insulating layer extend along a first axis parallel to the major surface;
the memory cell array unit further includes
a third memory string extending along the first axis along an extension of an extension axis of the first memory string, and
a filled insulating film having at least a part filled between the first memory string and the third memory string; and
the alignment mark unit further includes a mark unit filled insulating layer provided on the mark unit insulating layer, the mark unit filled insulating layer including a material same as a material of the filled insulating film.

5. The device according to claim 1, wherein:
the first memory string, the second memory string, and the device isolation insulating layer extend along a first axis parallel to the major surface,
the memory cell array unit further includes
a third memory string extending along the first axis along an extension of an extension axis of the first memory string, and
a filled insulating film having at least a part filled between the first memory string and the third memory string, and
the alignment mark unit further includes a mark unit filled insulating layer provided on the mark unit semiconductor layer, the mark unit filled insulating layer including a material same as the filled insulating film.

6. The device according to claim 1, wherein the semiconductor layer is a silicon substrate, and a material of the device isolation insulating layer includes at least one selected from silicon oxide and silicon nitride.

7. A method for manufacturing a semiconductor memory device, the device including a memory cell array unit and an alignment mark unit juxtaposed with the memory cell array unit, the memory cell array unit including a first memory string provided on a major surface of a semiconductor layer, a second memory string juxtaposed with the first memory string on the major surface, and a device isolation insulating layer partitioning the first memory string and the second memory string from each other, the alignment mark unit including a mark unit semiconductor layer and a mark unit insulating layer juxtaposed with the mark unit semiconductor layer, the mark unit semiconductor layer being a part of the semiconductor layer, the mark unit insulating layer including a material same as a material of the device isolation insulating layer, an upper surface of the mark unit semiconductor layer being included in a plane different from a plane including an upper surface of the mark unit insulating layer when a direction of the major surface side defines the direction of an upper direction, the method comprising:
forming a charge retaining film in a base body upper surface of a base body of a mark unit region, the base body including the semiconductor layer and the mark unit semiconductor layer, the alignment mark unit being formed in the mark unit region, the charge retaining film being used to form a charge retaining layer included in a memory cell included in the first memory string and a charge retaining layer included in a memory cell included in the second memory string;
making a mark unit trench in the charge retaining film and the base body;
filling an insulating layer into the mark unit trench; and
forming a difference in levels by causing an upper surface of the insulating layer filled into the mark unit trench to be included in a plane different from a plane including the base body upper surface of the base body of the mark unit region by etching at least one selected from the insulating layer filled into the mark unit trench and the base body upper surface of the base body of the mark unit region.

8. The method according to claim 7, wherein the forming of the difference in levels includes causing a distance from a plane parallel to the major surface and including the upper surface of the insulating layer filled into the mark unit trench to a plane parallel to the major surface and including the base body upper surface of the base body of the mark unit region to be not less than 40 nanometers.

9. The method according to claim 7, wherein the forming of the difference in levels includes forming the mark unit insulating layer by etching the insulating layer filled into the mark unit trench to cause the upper surface of the insulating layer to be positioned lower than the charge retaining film and higher than the base body upper surface.

10. The method according to claim 9, wherein the forming of the difference in levels includes causing a distance from a plane parallel to the major surface and including the upper surface of the mark unit semiconductor layer to a plane parallel to the major surface and including the upper surface of the mark unit insulating layer to be not less than 40 nanometers.

11. The method according to claim 9, further comprising:
patterning a gate electrode included in the memory cell included in the first memory string and a gate electrode included in the memory cell included in the second memory string after the etching of the insulating layer filled into the mark unit trench; and
forming the mark unit filled insulating layer above the insulating layer filled into the mark unit trench after the etching is performed to cause the insulating layer filled into the mark unit trench to recede to be lower than the charge retaining film.

12. The method according to claim 7, wherein
the insulating layer filled into the mark unit trench by the filling is used to form the mark unit insulating layer, and
the forming of the difference in levels includes
patterning a gate electrode included in the memory cell included in the first memory string and a gate electrode included in the memory cell included in the second memory string and removing the charge retaining film formed in the mark unit region, and
causing the base body upper surface to be lower than the mark unit insulating layer by etching the base body upper surface of the base body of the mark unit region exposed by the removing of the charge retaining film.

13. The method according to claim 12, wherein the forming of the difference in levels includes causing a distance from a plane parallel to the major surface and including the upper surface of the mark unit semiconductor layer to a plane parallel to the major surface and including the upper surface of the mark unit insulating layer to be not less than 40 nanometers.

14. The method according to claim 12, further comprising forming the mark unit filled insulating layer on the base body after the etching of the base body upper surface of the base body of the mark unit region exposed by the removing of the charge retaining film.

15. The method according to claim 7, wherein the charge retaining film includes at least one selected from polysilicon and silicon nitride.

16. A semiconductor wafer, comprising:
a memory cell array unit including
a first memory string provided on a major surface of a semiconductor layer,
a second memory string juxtaposed with the first memory string on the major surface, and
a device isolation insulating layer partitioning the first memory string and the second memory string from each other; and
an alignment mark unit juxtaposed with the memory cell array unit, the alignment mark unit including
a mark unit semiconductor layer, the mark unit semiconductor layer being a part of the semiconductor layer, and
a mark unit insulating layer juxtaposed with the mark unit semiconductor layer, the mark unit insulating layer including a material same as a material of the device isolation insulating layer,
an upper surface of the mark unit semiconductor layer being included in a plane different from a plane including an upper surface of the mark unit insulating layer when a direction of the major surface side defines the direction of an upper direction.

17. The wafer according to claim 16, wherein a distance from a plane parallel to the major surface and including the upper surface of the mark unit semiconductor layer to a plane parallel to the major surface and including the upper surface of the mark unit insulating layer being not less than 40 nanometers.

18. The wafer according to claim 16, wherein the upper surface of the mark unit semiconductor layer is positioned lower than the upper surface of the mark unit insulating layer.

19. The wafer according to claim 16, wherein:
the first memory string, the second memory string, and the device isolation insulating layer extend along a first axis parallel to the major surface;
the memory cell array unit further includes
a third memory string extending along the first axis along an extension of an extension axis of the first memory string, and
a filled insulating film having at least a part filled between the first memory string and the third memory string; and
the alignment mark unit further includes a mark unit filled insulating layer provided on the mark unit insulating layer, the mark unit filled insulating layer including a material same as a material of the filled insulating film.

20. The wafer according to claim 16, wherein:
the first memory string, the second memory string, and the device isolation insulating layer extend along a first axis parallel to the major surface,
the memory cell array unit further includes
a third memory string extending along the first axis along an extension of an extension axis of the first memory string, and
a filled insulating film having at least a part filled between the first memory string and the third memory string, and
the alignment mark unit further includes a mark unit filled insulating layer provided on the mark unit semiconductor layer, the mark unit filled insulating layer including a material same as the filled insulating film.
